(19) United States
(12) Patent Application Publication
(10) Pub. No.: US 2022/0229117 A1
(43) Pub. Date: Jul. 21, 2022

(54) GENERATION APPARATUS, PREDICTION SYSTEM, GENERATION METHOD, AND COMPUTER PROGRAM

(71) Applicant: GS Yuasa International Ltd., Kyoto (JP)

(72) Inventor: Toshihiro YABU, Kyoto (JP)

(21) Appl. No.: 17/615,014

(22) PCT Filed: May 19, 2020
(86) PCT No.: PCT/JP2020/019737

§ 371 Date: Nov. 29, 2021

(30) Foreign Application Priority Data
May 30, 2019 (JP) 2019-101443
Mar. 12, 2020 (JP) 2020-043462

(51) Int. Cl. G01R 31/367; G06F 3/0482; H02J 3/32; H02J 7/00; G01R 31/392

(52) U.S. Cl. CPC G01R 31/367; G06F 3/0482; H02J 7/0013; H02J 7/0047; G01R 31/392; H02J 3/32

(57) ABSTRACT

In the present invention, a display unit 50 of a pattern generation device 5 displays a reception screen for receiving a selection and/or an input regarding charging/discharging of a power storage system having a power storage device. An operation unit 51 receives, in the reception screen, a selection made from among multiple kinds of operations regarding charging/discharging. On the basis of the operation selected through the operation unit 51, a control unit 53 generates pattern data which is used for predicting a deterioration of the power storage device and which indicates transitions of charging/discharging amounts.

### CROSS REFERENCE TO RELATED APPLICATIONS

This application is a national stage application, filed under 35 U.S.C. § 371, of International Application No. PCT/JP2020/019737, filed May 19, 2020, which international application claims priority to and the benefit of Japanese Patent Application No. JP 2020-043462, filed Mar. 12, 2020 and Japanese Patent Application No. JP 2019-101443, filed May 30, 2019; the contents of all of which as are hereby incorporated by reference in their entireties.

### BACKGROUND

### Technical Field

The present invention relates to a generation apparatus, a prediction system, a generation method, and a computer program.

### Description of Related Art

An energy storage system including an energy storage apparatus that is charged by a generator such as a solar cell or a wind power generator and discharged as necessary has been widely used. The energy storage apparatus includes a plurality of energy storage devices (energy storage cells). A capacity (full charge capacity) of the energy storage apparatus decreases with repetition of charge-discharge (charge-discharge cycle) and elapse of time. The rate at which the capacity of the energy storage apparatus degrades varies depending on a state of charge (SOC), namely, an amount of electric power stored in the energy storage apparatus.

Patent Document JP-A-2018-169393 discloses a technique for predicting the capacity of the energy storage apparatus which decreases with the repetition of the charge-discharge and the elapse of time. In Patent Document JP-A-2018-169393, the decrease in capacity of the energy storage apparatus is predicted based on transition of the SOC.

### BRIEF SUMMARY

A manufacturer of the energy storage apparatus performs the following in order to propose the energy storage apparatus (energy storage system) that is considered to be optimal to a customer based on requirement of the customer.

(1) The manufacturer determines a configuration of the energy storage apparatus such as the number of energy storage cells in series or the number of energy storage cells in parallel.

(2) The manufacturer performs simulation (prediction) for a period (life) during which the energy storage apparatus having the determined configuration can satisfy the requirement of the customer under an assumed use environment.

The manufacturer repeats trial and error of determination and simulation, and proposes the energy storage apparatus considered to be optimal to the customer. Charge-discharge pattern data (hereinafter, simply referred to as “pattern data”) that appropriately simulates transition of a charge-discharge amount in the use environment is required in order to perform the simulation. Conventionally, the manufacturer produces the pattern data indicating the transition of the charge-discharge amount of the energy storage apparatus within a predetermined period such as one day or one month based on rough information presented from the customer or operation information in a similar energy storage system.

In order to propose the optimal energy storage apparatus to the customer by performing highly accurate simulation, the pattern data needs to appropriately simulate the transition of the charge-discharge amount when the energy storage system is actually operated. The pattern data is considerable data used for determining the configuration of the energy storage apparatus and predicting a life of the energy storage apparatus.

When the simulation is performed based on the pattern data set to excessively charge and discharge the energy storage apparatus as compared with the actual charge-discharge, the energy storage apparatus having an excessive configuration and high price is proposed as compared with the optimal energy storage apparatus that satisfies the requirement of the customer. When the simulation is performed based on the pattern data set such that the energy storage apparatus is excessively charged and discharged as compared with the actual charge-discharge, the energy storage apparatuses having an excessively small configuration and low price is proposed as compared with the optimal energy storage apparatus that satisfies the requirement of the customer. When the energy storage apparatus has the excessive configuration and high price, there is a high possibility that the manufacturer will miss (lose) a business opportunity. When the energy storage apparatus has the excessively small configuration and low price, there is a high possibility that the requirement of the customer will not be satisfied at an earlier stage than expected in the simulation after the energy storage system is delivered.

Accordingly, the manufacturer needs to generate the pattern data that appropriately simulates the transition of the charge-discharge amount in the use environment.

An object of the present invention is to provide a generation apparatus, a generation method, and a computer program for generating the pattern data indicating the transition of the charge-discharge amount, and a prediction system including the generation apparatus.

According to one aspect of the present invention, a generation apparatus includes: a screen display that displays a reception screen in order to receive at least one of selection or input related to charge-discharge of an energy storage system including an energy storage apparatus; a selection reception unit that accepts selection from a plurality of types of operations related to the charge-discharge on the reception screen; and a generation unit that generates pattern data that is used for prediction of degradation of the energy storage apparatus and indicates transition of a charge-discharge amount of the energy storage apparatus within a predetermined period based on the operation selected through the selection reception unit

According to another aspect of the present invention, a prediction system includes: the above described generation apparatus; a configuration reception unit that receives a configuration of the energy storage apparatus; and a prediction unit that predicts degradation of the energy storage apparatus based on the pattern data generated by the generation apparatus and a configuration received by the configuration reception unit.

According to still another aspect of the present invention, a generation method includes: displaying a reception screen in order to receive at least one of selection or input related to charge-discharge of an energy storage system including an energy storage apparatus; acquiring operation data indicating operation selected from a plurality of types of operations related to the charge-discharge on the reception screen; and generating pattern data that is used for prediction of degradation of the energy storage apparatus and indicates transition of a charge-discharge amount of the energy storage apparatus within a predetermined period based on acquired operation data.

According to yet another aspect of the present invention, a computer program causes a computer to execute: displaying a reception screen in order to receive at least one of selection or input related to charge-discharge of an energy storage system including an energy storage apparatus; acquiring operation data indicating operation selected from a plurality of types of operations related to the charge-discharge on the reception screen; and generating pattern data that is used for prediction of degradation of the energy storage apparatus and indicates transition of a charge-discharge amount of the energy storage apparatus within a predetermined period based on the acquired operation data.

According to the above aspects, the pattern data that appropriately simulates the transition of the charge-discharge amount in the use environment can be generated.

### BRIEF DESCRIPTION OF THE FIGURES

FIG. 1 is a block diagram illustrating a configuration of an energy storage apparatus.

FIG. 2 is a block diagram illustrating a configuration of a life prediction apparatus.

FIG. 3 is a flowchart illustrating a procedure of life prediction processing.

FIG. 4 is a schematic diagram illustrating a reception screen of a configuration content.

FIG. 5 is a graph illustrating transition of a charge-discharge amount.

FIG. 6 is a table illustrating a content of pattern data.

FIG. 7 is an explanatory view illustrating a first model of an energy storage system.

FIG. 8 is an explanatory view illustrating a second model of the energy storage system.

FIG. 9 is an explanatory view illustrating a third model of the energy storage system.

FIG. 10 is a block diagram illustrating a configuration of a pattern generation apparatus.

FIG. 11 is a flowchart illustrating a procedure of pattern generation processing.

FIG. 12 is a schematic view illustrating the reception screen of charge-discharge.

FIG. 13 is an explanatory view illustrating display of a plurality of types of operations.

FIG. 14 is an explanatory view illustrating a use example of the pattern generation apparatus and the life prediction apparatus.

FIG. 15 is an explanatory view illustrating an effect of the pattern generation apparatus.

FIG. 16 is a block diagram illustrating a configuration of an information processing apparatus.

FIG. 17 is an explanatory view of a pattern file.

FIG. 18 is a graph illustrating the transition of charge-discharge power.

FIG. 19 is a graph illustrating an output distribution.

FIG. 20 is a flowchart illustrating a procedure of acquisition processing.

FIG. 21 is a schematic diagram illustrating the reception screen that receives editing information.

FIG. 22 is a schematic diagram illustrating the reception screen that receives graph information.

FIG. 23 is a flowchart illustrating a procedure of editing processing.

FIG. 24 is a flowchart illustrating the procedure of the editing processing.

FIG. 25 is an explanatory view of an editing target folder.

FIG. 26 is a flowchart illustrating a procedure of transition display processing.

FIG. 27 is an explanatory view illustrating a display screen on which the transition of the charge-discharge power is indicated.

FIG. 28 is a flowchart illustrating a procedure of distribution display processing.

FIG. 29 is a flowchart illustrating the procedure of the distribution display processing.

FIG. 30 is an explanatory view illustrating the display screen on which the output distribution is displayed.

FIG. 31 is a flowchart illustrating the procedure of the life prediction processing.

FIG. 32 is an explanatory view illustrating a use example of the information processing apparatus.

### DETAILED DESCRIPTION OF VARIOUS EMBODIMENTS

A generation apparatus includes: a screen display that displays a reception screen in order to receive at least one of selection or input related to charge-discharge of an energy storage system including an energy storage apparatus; a selection reception unit that accepts selection from a plurality of types of operations related to the charge-discharge on the reception screen; and a generation unit that generates pattern data that is used for prediction of degradation of the energy storage apparatus and indicates transition of a charge-discharge amount of the energy storage apparatus within a predetermined period based on the operation selected through the selection reception unit

Because the pattern data is generated by selecting the operation from the plurality of types of operations on the reception screen, the pattern data is easily generated, and the pattern data can be generated in a short time. The manufacturer of the energy storage apparatus (energy storage system) can promptly present the transition of the charge-discharge amount indicated by pattern data to the customer. When the customer checks the transition of the charge-discharge amount and when the pattern data does not appropriately simulate the transition of the charge-discharge amount in the use environment, the manufacturer changes the content selected and/or input on the reception screen and generates the pattern data again. The manufacturer presents the transition of the charge-discharge amount indicated by the generated pattern data to the customer again. Because the pattern data can be generated in a short time, this series of actions can be repeated in a short time. As a result, the manufacturer can generate the pattern data that appropriately simulates the transition of the charge-discharge amount in the use environment and agree on the pattern data with the customer at the negotiation site. The pattern data agreed with the customer is used for the prediction (for example, a period until a capacity of the energy storage apparatus decreases to a predetermined value, namely, the prediction of the life) of the degradation of the energy storage apparatus.

The plurality of types of operations may include at least two of: operation in which only the charge is performed, operation in which only the discharge is performed, or operation in which the charge and the discharge are continuously performed once each.

Because these basic operations can be selected, various pattern data can be generated in a short time by combining at least two operations as necessary.

The generation apparatus may further include a power reception unit that receives input of both or one of a charge amount and a discharge amount on the reception screen for the operation selected through the selection reception unit. An element used for generating the pattern data by the generation unit may further include an input content input through the power reception unit.

For example, when the selected operation is the operation for performing both the charge and the discharge, the user inputs both the charge amount and the discharge amount. For example, when the selected operation is the operation for performing only the charge, the user inputs the charge amount. In the generation of the pattern data, the input content of both or one of the charge amount and the discharge amount is also used. For this reason, the pattern data that more appropriately simulates the transition of the charge-discharge amount in the use environment is generated.

The generation apparatus may further include a first efficiency reception unit that receives input of transmission efficiency of a power line of the energy storage system on the reception screen. The element used for generating the pattern data by the generation unit may further include the transmission efficiency input through the first efficiency reception unit.

Because the transmission efficiency of the power line is also used in the generation of the pattern data, pattern data that more appropriately simulates the transition of the charge-discharge amount in the use environment is generated.

The energy storage system may include a converter that converts voltage input from the outside into a DC voltage suitable for charging the energy storage apparatus and converts the DC voltage input from the energy storage apparatus into voltage suitable for outputting to the outside, and the generation apparatus may include a second efficiency reception unit that receives input of conversion efficiency of the converter on the reception screen. The element used for generating the pattern data by the generation unit may further include the conversion efficiency input through the second efficiency reception unit.

The conversion efficiency of the converter is also used in generating the pattern data. For this reason, the pattern data that more appropriately simulates the transition of the charge-discharge amount in the use environment is generated.

The energy storage system may include a transformer that converts amplitude of the AC voltage input from the outside and outputs the AC voltage in which amplitude is converted to the converter, and the generation apparatus may include a third efficiency reception unit that receives the input of the conversion efficiency of the transformer on the reception screen. The element used for generating the pattern data by the generation unit may further include the conversion efficiency input through the third efficiency reception unit.

Because the conversion efficiency of the transformer is also used in the generation of the pattern data, the pattern data that more appropriately simulates the transition of the charge-discharge amount in the use environment is generated.

The generation apparatus may further include a period reception unit that receives input of a period during which the charge or the discharge is performed on the reception screen for the operation selected through the selection reception unit. An element used for generating the pattern data by the generation unit may further include an input content input through the period reception unit.

Because the period during which the charge or the discharge is performed is used in the generation of the pattern data, the pattern data that more appropriately simulates the transition of the charge-discharge amount in the use environment is generated.

The generation apparatus may include a second selection reception unit that receives selection of one operation from the plurality of types of second operations related to the operation executed in the remaining period of the predetermined period on the receiving screen when a total of periods input through the period reception unit is less than the predetermined period. The element used for generating the pattern data by the generation unit may further include the operation selected through the second selection reception unit. Each of the plurality of types of second operations may be different from the plurality of types of operations.

The user may select the operation executed in the remaining period of the setting period from the plurality of types of second operations. For this reason, the generation of the pattern data is further facilitated.

The screen display may display the plurality of types of operations on the reception screen.

Because the plurality of types of operations are displayed, the user can easily grasp the selectable operation in the generation of the pattern data.

The generation apparatus may include a transition display that displays the transition of the charge-discharge amount indicated by the pattern data generated by the generation unit.

Because the transition of the charge-discharge amount indicated by the pattern data is displayed, the user can intuitively grasp the transition of the charge-discharge amount.

A prediction system includes: the above described generation apparatus; a configuration reception unit that receives a configuration of the energy storage apparatus; and a prediction unit that predicts degradation of the energy storage apparatus based on the pattern data generated by the generation apparatus and the configuration received by the configuration reception unit.

The prediction unit may predict a period until the capacity of the energy storage apparatus decreases to a predetermined value as the prediction of the degradation of the energy storage apparatus.

A generation method includes: displaying a reception screen in order to receive at least one of selection or input related to charge-discharge of an energy storage system including an energy storage apparatus; acquiring operation data indicating operation selected from a plurality of types of operations related to the charge-discharge on the reception screen; and generating pattern data that is used for prediction of degradation of the energy storage apparatus and indicates transition of a charge-discharge amount of the energy storage apparatus within a predetermined period based on the acquired operation data.

A computer program causes a computer to execute: displaying a reception screen in order to receive at least one of selection or input related to charge-discharge of an energy storage system including an energy storage apparatus; acquiring operation data indicating operation selected from a plurality of types of operations related to the charge-discharge on the reception screen; and generating pattern data that is used for prediction of degradation of the energy storage apparatus and indicates transition of a charge-discharge amount of the energy storage apparatus within a predetermined period based on the acquired operation data.

Hereinafter, the present invention will be described in detail based on the drawings illustrating an embodiment.

### First Embodiment

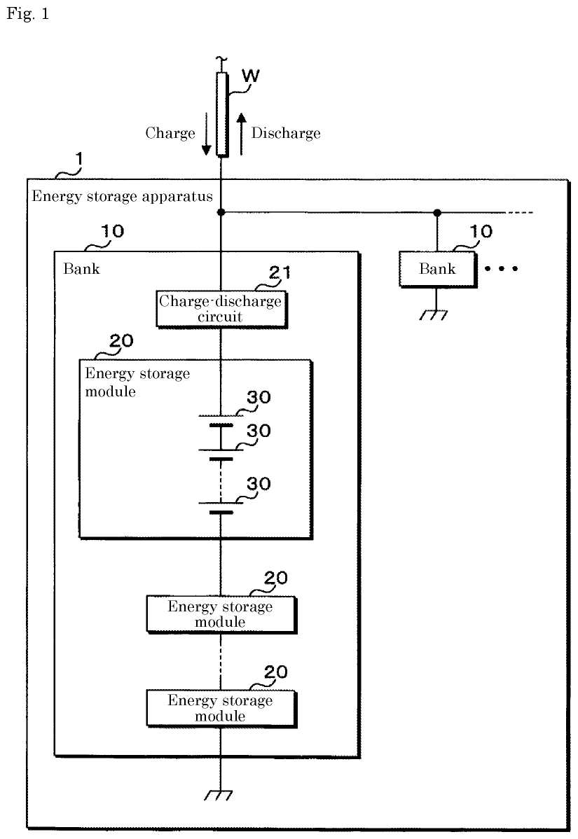

FIG. 1 is a block diagram illustrating a configuration of an energy storage apparatus 1. The energy storage apparatus 1 is connected to one end of a power line W.

The energy storage apparatus 1 includes K (K is a natural number) banks (also referred to as strings) 10 connected in parallel. One end of each bank 10 is connected to one end of the power line W. The other end of each bank 10 is grounded. Each bank 10 includes M (M is a natural number) energy storage modules 20 connected in series. Each energy storage module 20 includes N (N is a natural number) energy storage devices 30 connected in series. The energy storage device 30 is what is called an energy storage cell. For example, the energy storage device 30 is a lithium ion battery.

The power supplied through the power line W is supplied to the plurality of energy storage devices 30 included in each bank 10, and each energy storage device 30 is charged. Thus, the energy storage module 20 and the bank 10 are charged. Each energy storage device 30 discharges power through the power line W. Thus, the energy storage module 20 and the bank 10 release the power through the power line W.

Each bank 10 includes a charge-discharge circuit 21 in addition to the plurality of energy storage modules 20. The power is supplied to each energy storage device 30 through the charge-discharge circuit 21. Each energy storage device 30 discharges the power through the charge-discharge circuit 21.

For example, the charge-discharge circuit 21 includes a switch or a breaker. The charge-discharge circuit 21 switches the switch or the breaker to on or off, thereby stopping charge to the plurality of energy storage modules 20, stopping discharge from the plurality of energy storage modules 20, releasing the charge stop, and releasing the discharge stop.

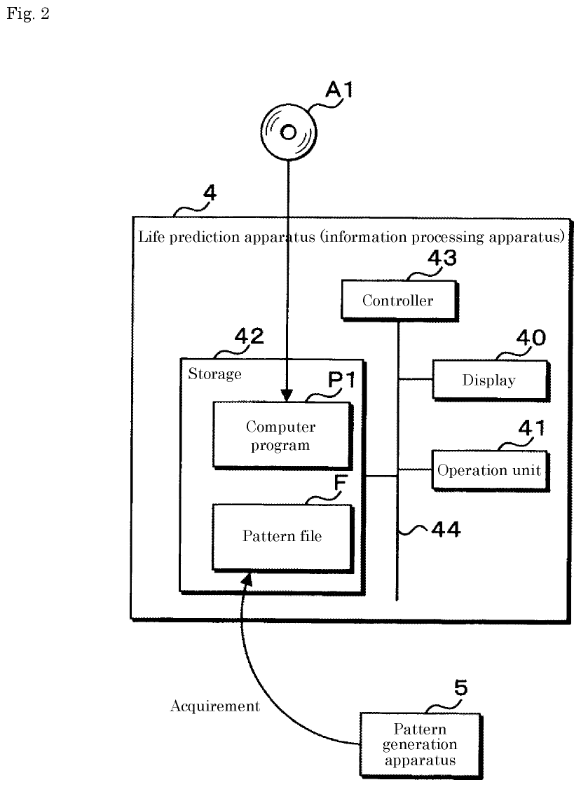

FIG. 2 is a block diagram illustrating a configuration of a life prediction apparatus 4. The life prediction apparatus 4 is a personal computer, a tablet, or the like, and is an apparatus that predicts a life of the energy storage apparatus 1, namely, a period from the start of the use of the energy storage apparatus 1 until the capacity (full charge capacity) decreases to a predetermined value, as the prediction of the degradation of the energy storage apparatus 1. There is a state of health (SOH) as an index indicating a degradation degree of the capacity of the energy storage apparatus 1. SOH is a ratio of the capacity of the energy storage apparatus 1 when the capacity of the energy storage apparatus 1 at the start of the use is set to 100%. The unit of SOH is percent. For example, the life is a period until the SOH decreases to 70%.

The life prediction apparatus 4 includes a display 40, an operation unit 41, a storage 42, and a controller 43. These are connected to an internal bus 44. The display 40 displays various screens according to an instruction from the controller 43. The operation unit 41 includes a touch panel, a keyboard, and a mouse. The operation unit 41 is operated by a user of the life prediction apparatus 4, and receives various inputs from the user.

The storage 42 is a nonvolatile memory. A computer program P1 is stored in the storage 42. For example, the controller 43 includes a processing device such as a central processing unit (CPU). The processing device (computer) of the controller 43 executes the computer program P1 to execute life prediction processing for predicting the life of the energy storage apparatus 1. The number of processing devices included in the controller 43 may be two or more. In this case, the plurality of processing devices may cooperatively execute various pieces of processing including the life prediction processing according to the computer program P1.

The computer program P1 may be provided to the life prediction apparatus 4 using a non-transitory recording medium A1 in which the computer program P1 is readably recorded. For example, the recording medium A1 is a portable memory. Examples of the portable memory include a CD-ROM, a universal serial bus (USB) memory, an SD card, a micro SD card, and a compact flash (registered trademark). When the recording medium A1 is a portable memory, the processing device of the controller 43 may read the computer program P1 from the recording medium A1 using a reading apparatus (not illustrated) and write the read computer program P1 into the storage 42. When the life prediction apparatus 4 includes a communication unit (not illustrated) that communicates with an external apparatus, the computer program P1 may be provided to the life prediction apparatus 4 by communication through the communication unit. In this case, the processing device of the controller 43 may acquire the computer program P1 through the communication unit and write the acquired computer program P1 in the storage 42.

The storage 42 stores a pattern file F including charge-discharge pattern data (hereinafter, simply referred to as “pattern data”) indicating the transition of the charge-discharge amount of the energy storage apparatus 1 within a previously setting period. The setting period is one day, one week, one month, one year, or the like. As described later, the pattern file F of the energy storage apparatus 1 is generated by a pattern generation apparatus 5. The controller 43 of the life prediction apparatus 4 acquires the pattern file F from the pattern generation apparatus 5, and writes the acquired pattern file F in the storage 42. A system including the life prediction apparatus 4 and the pattern generation apparatus 5 corresponds to a prediction system.

The controller 43 acquires the pattern file F by various methods. The life prediction apparatus 4 may include the communication unit that receives the pattern file F transmitted by the pattern generation apparatus 5 in a wired or wireless manner. The life prediction apparatus 4 may include a reading unit that reads data from the portable memory, and acquire the pattern file F generated by the pattern generation apparatus 5 from the portable memory.

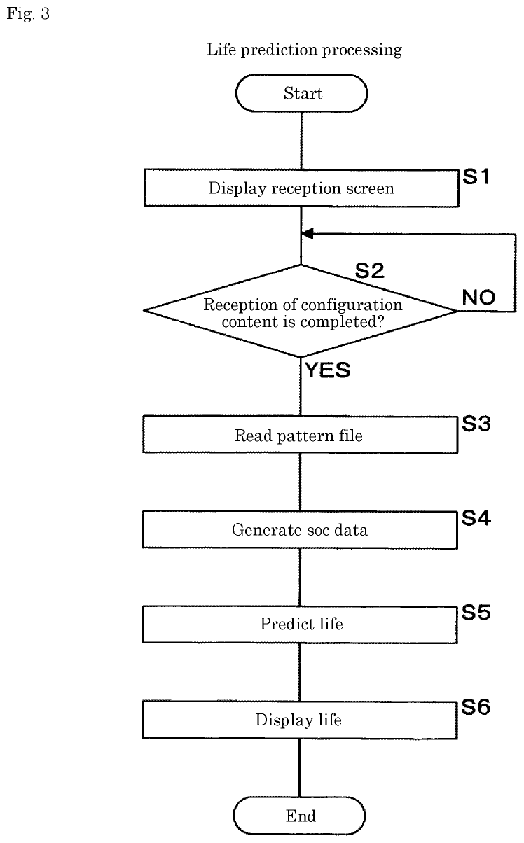

FIG. 3 is a flowchart illustrating a procedure of life prediction processing. The user of the life prediction apparatus 4 instructs execution of the life prediction processing by operating the operation unit 41. When the operation unit 41 receives the instruction to execute the life prediction processing and when the pattern file F is stored in the storage 42, the controller 43 executes the life prediction processing. In the life prediction processing, first the controller 43 instructs the display 40 to display a reception screen in order to receive a configuration content of the energy storage apparatus 1 (step S1).

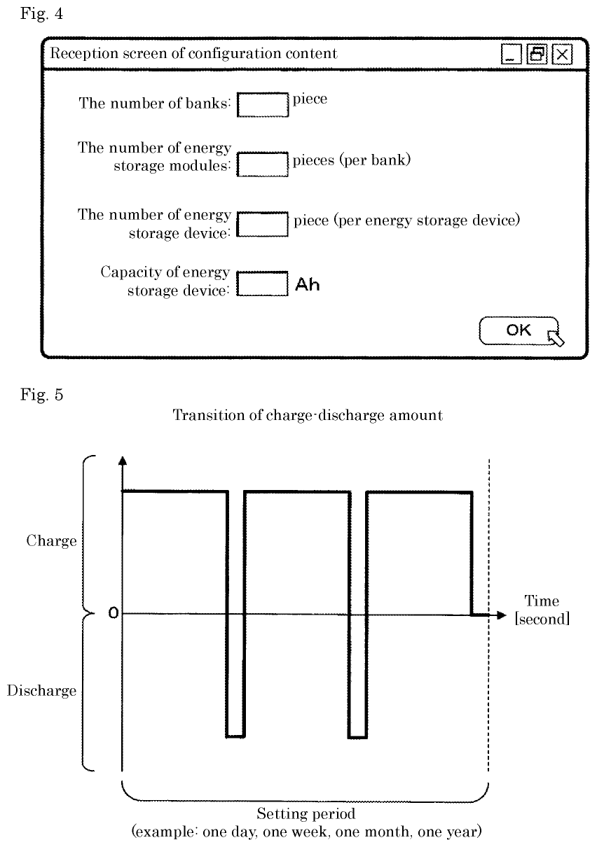

FIG. 4 is a schematic diagram illustrating the reception screen of the configuration content. As illustrated in FIG. 4, the configuration content of the energy storage apparatus 1 includes the number of banks 10, the number of energy storage modules 20 included in each bank 10, the number of energy storage devices 30 included in each energy storage module 20, and the capacity of each energy storage device 30. The number of banks 10 corresponds to a parallel number. Each of the number of energy storage modules 20 and the number of energy storage devices 30 corresponds to the number of series. The user of the life prediction apparatus 4 operates the operation unit 41 on the reception screen of the configuration content to input the configuration content of the energy storage apparatus 1, specifically, the number of banks 10, the number of energy storage modules 20, the number of energy storage devices 30, the capacity of each energy storage device 30, and the like. The operation unit 41 receives the configuration content of the energy storage apparatus 1 input by the user. The operation unit 41 functions as the configuration reception unit. The user clicks a button indicating “OK” by operating the operation unit 41 on the reception screen of the configuration content. Thus, the reception of the configuration contents is completed. When the reception of the configuration contents is completed, the controller 43 acquires configuration data indicating the configuration content received by the operation unit 41.

At least one of items of the configuration content may be the item selecting one numerical value from a plurality of numerical values instead of the item in which a numerical value is input. In this case, the operation unit 41 receives the configuration content of the energy storage apparatus 1 input by the user, and receives the configuration content of the energy storage apparatus 1 selected by the user. When the reception of the configuration content is completed, the controller 43 acquires the configuration data indicating the configuration content. The number of items in which selection or input of the configuration content is input may be at least one, and is not limited to four. For example, the type of the energy storage device may be included as the item in which the selection or input of the configuration content is received. For example, an example of the type of the energy storage device includes a lithium ion battery.

After executing step S1, the controller 43 determines whether the reception of the configuration content is completed (step S2). When determining that the reception of the configuration content is not completed (NO in S2), the controller 43 executes step S2 again and waits until the reception of the configuration content is completed. When determining that the reception of the configuration contents is completed (YES in S2), the controller 43 reads the pattern file F from the storage 42 (step S3). As described above, the pattern file F includes the pattern data indicating the transition of the charge-discharge amount of the energy storage apparatus 1 within the setting period.

FIG. 5 is a graph illustrating the transition of the charge-discharge amount. In FIG. 5, a horizontal axis indicates time, and the unit of time is seconds. A vertical axis indicates the charge-discharge amount, and the unit of the charge-discharge amount is watt. When the charge-discharge amount is positive, it indicates that the charge is being performed. The charge amount is the power supplied to the energy storage apparatus 1, and is represented by an absolute value of the charge-discharge amount. When the charge-discharge amount is negative, it indicates that the discharge is being performed. The discharge amount is the power discharged from the energy storage apparatus 1, and is an absolute value of the charge-discharge amount. Assuming that the charge-discharge amount changes as illustrated in FIG. 5 within the setting period, the life of the energy storage apparatus 1 is predicted.

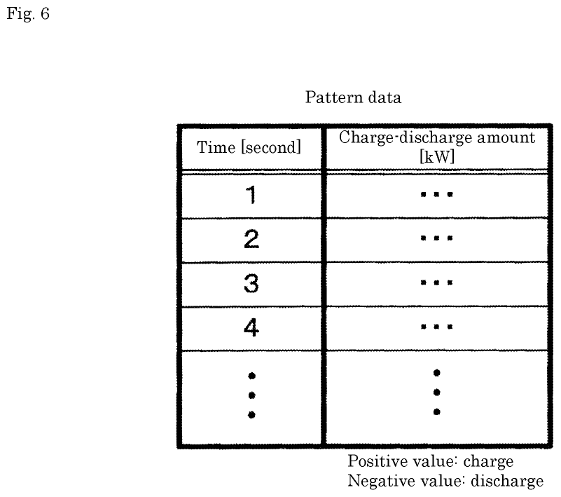

FIG. 6 is a table illustrating a content of pattern data. As illustrated in FIG. 6, the pattern data indicates the charge-discharge amount at each of a plurality of time points engraved at a predetermined time, for example, at intervals of one second. When the setting period is one day (86400 seconds), the charge-discharge amount corresponding to the period from 1 second to 86400 seconds is indicated.

Subsequently, as illustrated in FIG. 3, the controller 43 generates SOC data indicating the transition of the SOC of the energy storage apparatus 1 based on the pattern data included in the pattern file F read in step S3 (step S4).

The controller 43 predicts the transition of the charge-discharge amount based on the pattern data indicating the transition of the charge-discharge amount of the energy storage apparatus 1 within the setting period. For example, when the setting period is one day, the controller 43 predicts the transition of the daily charge-discharge amount based on the pattern data.

Based on the transition of the predicted charge-discharge amount, for example, the controller 43 calculates a total amount of the charge amount and the discharge amount in the period from the start of the use of the energy storage apparatus 1 to a calculation time point. The controller 43 calculates the SOC at the calculation time point by subtracting the total amount of the discharge amount from the total amount of the charge amount. The controller 43 calculates the SOC at each time point by changing the calculation time point to each of a plurality of time points engraved at a predetermined time, for example, at an interval of one second, and generates the SOC data indicating the transition of the SOC.

Subsequently, the controller 43 predicts the life of the energy storage apparatus 1 as the prediction of the degradation of the energy storage apparatus 1 based on the SOC data generated in step S4 and the configuration content received by the operation unit 41 (step S5). As described above, the life is the period from the start of the use until the capacity of the energy storage apparatus 1 decreases to a predetermined value, for example, the period until the SOH decreases to 70%. The prediction of the life is an example of the prediction of the degradation. The controller 43 functions as the prediction unit.

The prediction of the life of the energy storage apparatus 1 based on the SOC data can be implemented using a known technique, for example, a technique described in JP-A-2018-169393. JP-A-2018-169393 discloses a configuration estimating the degradation of the energy storage device (the decrease in capacity of the energy storage device) based on the SOC data. Using the technique described in JP-A-2018-169383, the SOH at each of the plurality of time points engraved at predetermined intervals, for example, intervals of one second is calculated, and the life, for example, the period during which the SOH decreases to 70% is predicted.

Subsequently, the controller 43 instructs the display 40 to display the life predicted in step S5 (step S6), and ends the life prediction processing.

The user of the life prediction apparatus 4 repeatedly executes the life prediction processing, and selects or inputs various configuration contents as the configuration content of the energy storage apparatus 1. Thus, the user searches the optimum configuration content of the energy storage apparatus 1 that satisfies the requirement of the customer who is scheduled to order the energy storage apparatus 1. The user of the life prediction apparatus 4, for example, the manufacturer of the energy storage apparatus 1 proposes the energy storage apparatus 1 having the optimum configuration content to the customer.

The generation of the pattern file F generated by the pattern generation apparatus 5 will be described below. A first model, a second model, and a third model described below are assumed as a model of the energy storage system including the energy storage apparatus 1.

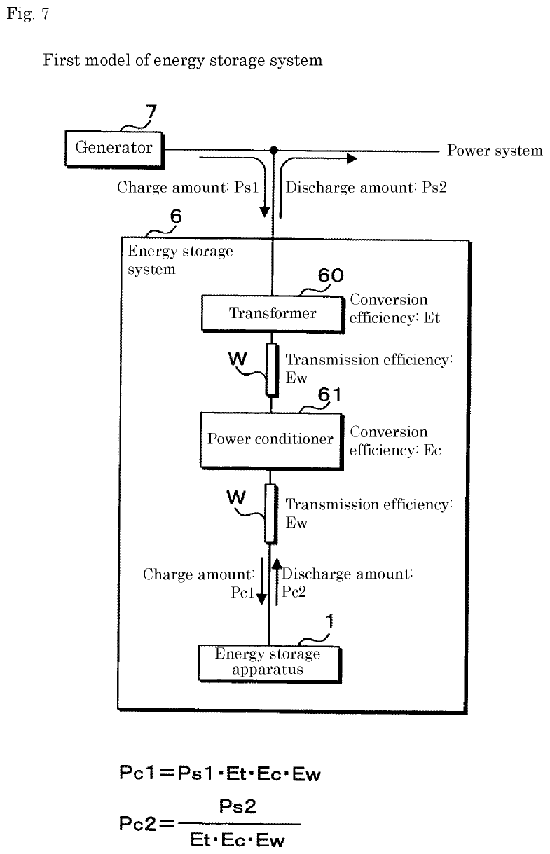

FIG. 7 is an explanatory view illustrating a first model of an energy storage system 6. In the first model, the energy storage system 6 is connected to a generator 7 and a connection node between the power systems. For example, the generator 7 is a wind power generator, and generates the AC power. The generator 7 supplies the generated AC power to the energy storage system 6 and the power system. For example, the power system is connected to a building such as a factory or a home. The AC power is supplied to the building through the power system. When the generator 7 supplies the AC power to the energy storage system 6, the energy storage system 6 is charged. For example, when the generator 7 stops power generation, the energy storage system 6 discharges the AC power to the power system.

In addition to the energy storage apparatus 1, the energy storage system 6 includes a transformer 60, a power conditioner 61, and two power lines W, W. The transformer 60 is connected to a connection node between the generator 7 and the power system. The transformer 60 is connected to the power conditioner 61 through the power line W. The power conditioner 61 is connected to the energy storage apparatus 1 through the power line W.

The transformer 60 converts the amplitude of the AC voltage related to the AC power generated by the generator 7, and outputs the AC voltage in which the amplitude is converted to the power conditioner 61 through the power line W. The power conditioner 61 converts the AC voltage input from the transformer 60 into a DC voltage suitable for the charge of the energy storage apparatus 1, and supplies the DC power related to the converted DC voltage to the energy storage apparatus 1 through power line W. Accordingly, the energy storage apparatus 1 is charged.

For example, when the generator 7 stops the power generation, the energy storage apparatus 1 supplies the DC power to the power conditioner 61 through the power line W. The power conditioner 61 converts the DC voltage input from the energy storage apparatus 1 into the AC voltage suitable for the output to the transformer 60, and outputs the converted AC voltage to the transformer 60 through the power line W. The transformer 60 converts the amplitude of the AC voltage input from the power conditioner 61, and supplies the AC power related to the AC voltage in which the amplitude is converted to the power system. In the energy storage system 6, the power is transmitted through the power line W. The power conditioner 61 functions as the converter.

As illustrated in FIG. 7, charge amounts to the energy storage apparatus 1 and the energy storage system 6 are referred to as Psi and Pcl, respectively. Discharge amounts from the energy storage apparatus 1 and the energy storage system 6 are referred to as Ps2 and Pc2, respectively. As described above, the charge amount is the power supplied to the energy storage apparatus 1 or the energy storage system 6. The discharge amount is the power discharged from the energy storage apparatus 1 or the energy storage system 6. The conversion efficiencies of the transformer 60 and the power conditioner 61 are referred to as Et and Ec, respectively. The transmission efficiency of the entire two power lines W, W is referred to as Ew. Each of the conversion efficiencies Et, Ec and the transmission efficiency Ew is represented by a value exceeding zero and less than or equal to 1.

The charge amount Pc1 to the energy storage apparatus 1 is expressed by the following equation (1). A discharge amount Pc2 from the energy storage apparatus 1 is expressed by the following equation (2). “·” represents a product.

$$\begin{matrix}P c 1 = P s 1 \cdot E t \cdot E c \cdot E w & ( 1 ) \\ P c 2 = P s 2 / ( E t \cdot E c \cdot E w ) & ( 2 )\end{matrix}$$

For example, the manufacturer of the energy storage apparatus 1 is requested by a customer to present the transition of the charge-discharge amount of the energy storage system 6, the conversion efficiency of the transformer 60 and the power conditioner 61, and the transmission efficiency of the power line W. The manufacturer produces the pattern data indicating the transition of the charge-discharge amount of the energy storage apparatus 1 within the setting period using the transition of the charge-discharge amount, the conversion efficiency, the transmission efficiency, and the equations (1) and (2).

The charge-discharge amount of the energy storage system 6 is defined similarly to the charge-discharge amount of the energy storage apparatus 1. When the charge-discharge amount is positive, it indicates that the energy storage system 6 is being charged. The charge amount is the power supplied to the energy storage system 6, and is represented by an absolute value of the charge-discharge amount. When the charge-discharge amount is negative, it indicates that the discharge is being performed. The discharge amount is the power discharged from energy storage system 6, and is the absolute value of the charge-discharge amount.

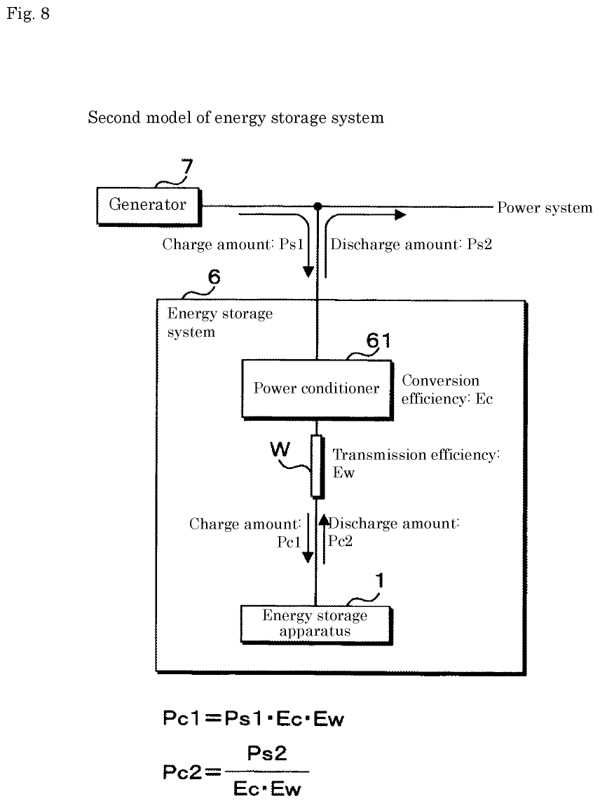

FIG. 8 is an explanatory view illustrating a second model of the energy storage system 6. The energy storage system 6 is connected to the generator 7 and the connection node between the power systems. The energy storage system 6 includes the energy storage apparatus 1, the power conditioner 61, and the power line W. The power conditioner 61 is connected to the generator 7 and the connection node between the power systems. The power conditioner 61 is connected to the energy storage apparatus 1 through the power line W.

In the energy storage system 6, the energy storage apparatus 1 operates similarly to the first model. The power conditioner 61 converts the AC voltage input from generator 7 into the DC voltage suitable for the charge of the energy storage apparatus 1, and supplies the DC power related to the converted DC voltage to the energy storage apparatus 1 through the power line W. The power conditioner 61 converts the DC voltage input from the energy storage apparatus 1 into the AC voltage suitable for the output to the power system, and supplies the AC power related to the AC voltage to the power system.

The charge amount Pc1 to the energy storage apparatus 1 is expressed by the following equation (3). The discharge amount Pc2 from the energy storage apparatus 1 is expressed by the following equation (4).

$$\begin{matrix}P c 1 = P s 1 \cdot E c \cdot E w & ( 3 ) \\ P c 2 = P s 2 / ( E c \cdot E w ) & ( 4 )\end{matrix}$$

The equation (3) is obtained by substituting one for the conversion efficiency Et of the transformer 60 in the equation (1). The equation (4) is obtained by substituting one for the conversion efficiency Et of the transformer 60 in the equation (2).

For example, the manufacturer of the energy storage apparatus 1 is requested by the customer to present the transition of the charge-discharge amount of the energy storage system 6, the conversion efficiency of the power conditioner 61, and the transmission efficiency of the power line W. The manufacturer produces the pattern data indicating the transition of the charge-discharge amount of the energy storage apparatus 1 within the setting period using the transition of the charge-discharge amount, the conversion efficiency, the transmission efficiency, and the equations (3) and (4).

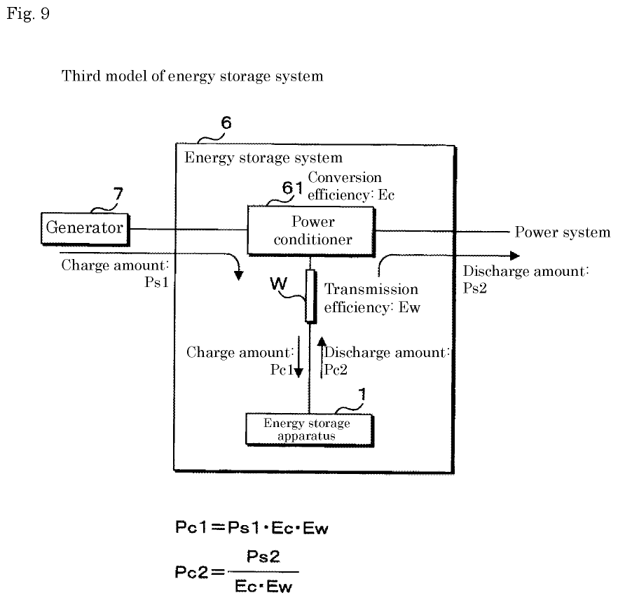

FIG. 9 is an explanatory view illustrating a third model of the energy storage system 6. Similarly to the second model, the energy storage system 6 includes the energy storage apparatus 1, the power conditioner 61, and the power line W. The power conditioner 61 is separately connected to the generator 7 and the power system. The power conditioner 61 is connected to the energy storage apparatus 1 through the power line W.

The generator 7 generates the DC or AC power, and supplies the generated DC or AC power to the power conditioner 61. The power conditioner 61 converts the voltage related to the power supplied from the generator 7 into the AC voltage in which the frequency and the amplitude are suitable for the power system, and supplies the AC power related to the converted AC voltage to the power system. The power conditioner 61 converts the voltage input from generator 7 into the DC voltage suitable for the charge of the energy storage apparatus 1, and supplies the DC power related to the converted DC voltage to the energy storage apparatus 1.

The energy storage apparatus 1 operates similarly to the first model and the second model. The power conditioner 61 converts the DC voltage input from the energy storage apparatus 1 into the AC voltage suitable for the output to the power system, and supplies the AC power related to the converted AC voltage to the power system.

Similarly to the second model, the charge amount Pc1 to the energy storage apparatus 1 is expressed by the equation (3), and the discharge amount Pc2 from the energy storage apparatus 1 is expressed by the equation (4). As described above, each of the equations (3) and (4) is obtained by substituting one for the conversion efficiency Et of the transformer 60 in the equations (1) and (2).

For example, the manufacturer of the energy storage apparatus 1 is requested by the customer to present the transition of the charge-discharge amount of the energy storage system 6, the conversion efficiency of the power conditioner 61, and the transmission efficiency of the power line W. The manufacturer produces the pattern data indicating the transition of the charge-discharge amount of the energy storage apparatus 1 within the setting period using the transition of the charge-discharge amount, the conversion efficiency, the transmission efficiency, and the equations (3) and (4).

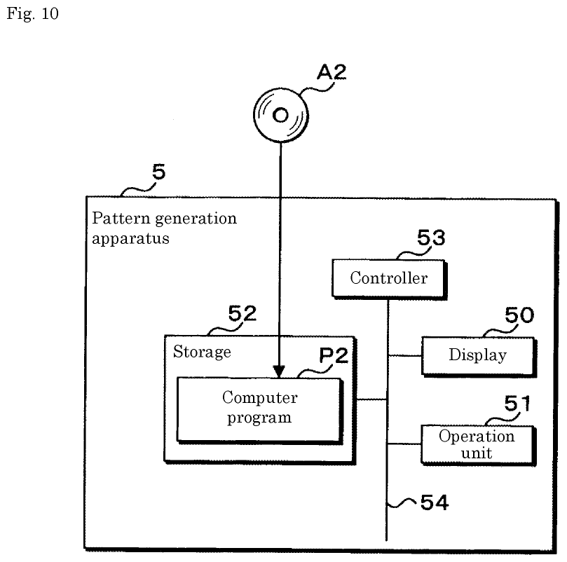

FIG. 10 is a block diagram illustrating a configuration of the pattern generation apparatus 5. The pattern generation apparatus 5 is a personal computer, a tablet, or the like, and generates the pattern file F including pattern data as described above. The pattern generation apparatus 5 includes a display 50, an operation unit 51, a storage 52, and a controller 53. These are connected to an internal bus 54.

The display 50 displays various screens according to the instruction of the controller 53. The operation unit 51 includes a touch panel, a keyboard, and a mouse. The operation unit 51 is operated by the user of the pattern generation apparatus 5, and receives various inputs from the user.

The storage 52 is a nonvolatile memory. The storage 52 stores a computer program P2. The controller 53 includes a processing device, for example, a CPU. The processing device (computer) of the controller 53 executes pattern generation processing for generating the pattern file F by executing the computer program P2. The number of processing devices included in the controller 53 may be at least two. In this case, the plurality of processing devices may cooperatively execute various pieces of processing including the pattern generation processing according to the computer program P2.

The computer program P2 may be provided to the pattern generation apparatus 5 using a non-transitory recording medium A2 in which the computer program P2 is recorded in a readable manner. For example, the recording medium A2 is a portable memory. In this case, the processing device of the controller 53 may read the computer program P2 from the recording medium A2 using a reading apparatus (not illustrated), and write the read computer program P2 in the storage 52. Furthermore, when the pattern generation apparatus 5 includes a communication unit (not illustrated) that communicates with an external apparatus, the computer program P2 may be provided to the pattern generation apparatus 5 by communication through the communication unit. In this case, the processing device of the controller 53 may acquire the computer program P2 through the communication unit, and write the acquired computer program P2 in the storage 52.

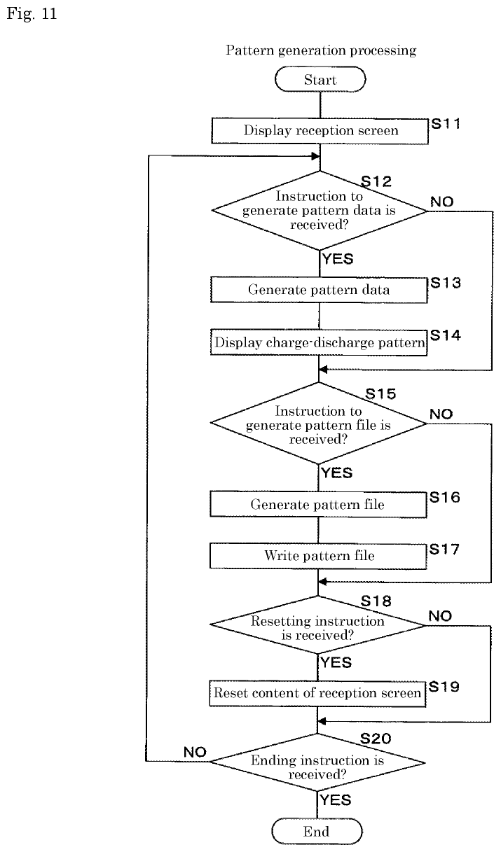

FIG. 11 is a flowchart illustrating a procedure of the pattern generation processing. The user of the pattern generation apparatus 5 instructs the execution of the pattern generation processing by operating the operation unit 51. When the operation unit 51 receives the instruction to execute the pattern generation processing, the controller 53 executes the pattern generation processing. In the pattern generation processing, first the controller 53 instructs the display 50 to display the reception screen in order to receive the selection and input related to the charge-discharge of the energy storage system 6 (step S11). The display 50 functions as the screen display.

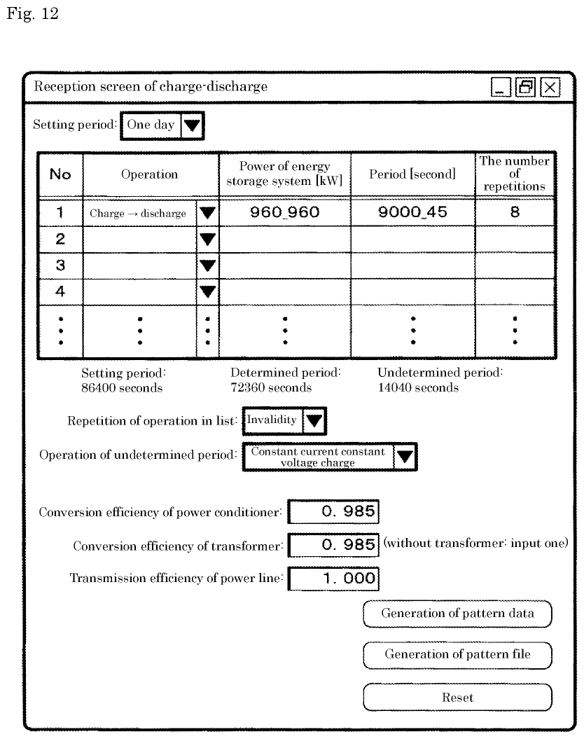

FIG. 12 is a schematic view illustrating the reception screen of the charge-discharge. The user of the pattern generation apparatus 5 performs various selections and inputs by operating the operation unit 41 on the reception screen of the charge-discharge. As illustrated in FIG. 12, first the user determines the setting period. When the user clicks the triangle button of the setting period, a plurality of previously candidate periods are displayed for the setting period. For example, the plurality of candidate periods are one day, one week, one month, and one year. The user selects one from the plurality of candidate periods. In the example of FIG. 12, one day is selected as the setting period.

Subsequently, on the reception screen of the charge-discharge, the user selects one or the plurality of types of operations from the plurality of types of operations related to the charge-discharge of the energy storage system 6. The plurality of types of operations are previously set. The user clicks the triangle button in the field indicating the operation on the reception screen of the charge-discharge. Accordingly, the display 50 displays a plurality of types of operations related to the charge-discharge of the energy storage system 6.

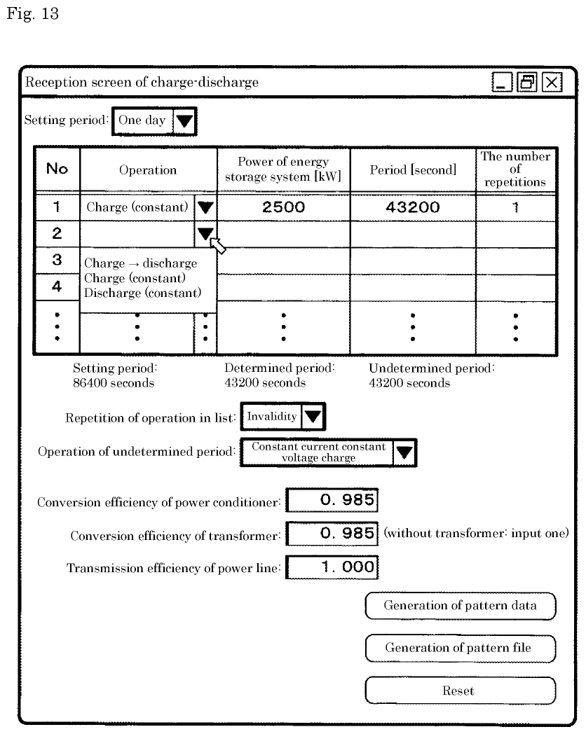

FIG. 13 is an explanatory diagram illustrating the display of a plurality of types of operations. As illustrated in FIG. 13, the display 50 displays a plurality of types of operations by clicking a triangle button of the operation. In the example of FIG. 13, three types of operations are illustrated. “Charge→discharge” is the operation in which the energy storage system 6 discharges after charging the energy storage system 6. In “charge→discharge”, the charge and the discharge are continuously performed once. “Charge (constant)” is the operation for performing only the charge in which the charging amount is constant. “Discharge (constant)” is the operation for performing only the discharge in which the discharge amount is constant.

The user selects one operation from the plurality of types of displayed operations. The operation unit 51 receives the selection from the plurality of types of operations related to the charge-discharge of the energy storage system 6 on the reception screen of the charge-discharge. The operation unit 51 functions as the selection reception unit.

As described above, because the plurality of types of operations are displayed as illustrated in FIG. 13, the user of the pattern generation apparatus 5 can easily grasp the selectable operation in the generation of the pattern data.

In FIG. 13, the three types of operations displayed by clicking the triangle button may include operations different from “charge→discharge”, “charge (constant)”, and “discharge (constant)”. For example, the three types of operations may include the operation for charging the energy storage system 6 after the energy storage system 6 is discharged, the operation for only performing the charge in which the charge amount increases or decreases at a constant inclination, or the operation for only performing the discharge in which the discharge amount increases or decreases at a constant inclination.

The number of types displayed by clicking the triangle button may be two or at least four instead of three.

As illustrated in FIGS. 12 and 13, the user can select the plurality of types of operations as the operation executed within the setting period. For example, the user can select “charge (constant)” as the operation of No. 1 and “discharge (constant)” as the operation of No. 2. Within the setting period, the operation is sequentially executed from the operation of No. 1.

Subsequently, the user operates the operation unit 51 to input the power of the energy storage system 6, namely, both or one of the charge amount and the discharge amount for the selected operation. The operation unit 51 receives the input of both or one of the charge amount and the discharge amount on the reception screen of the charge-discharge. In the example of FIG. 12, because “charge→discharge” is selected, the user inputs the charge amount to the left side of the input field and the discharge amount to the right side of the input field as the power of the energy storage system 6. In the example of FIG. 13, because “charge (constant)” is selected, the user inputs the charge amount as the power of the energy storage system 6. The operation unit 51 also functions as the power reception unit.

Subsequently, the user operates the operation unit 51 to input the period during which the charge or the discharge is performed for the selected operation on the reception screen of the charge-discharge. The operation unit 51 receives the input of the period during which the charge or the discharge is performed on the reception screen of the charge-discharge. In the example of FIG. 12, because “charge→discharge ” is selected, the user inputs the period during which the charge is performed on the left side of the input field and inputs the period during which the discharge is performed on the right side of the input field. In the example of FIG. 13, because “charge (constant)” is selected, the user inputs the period during which the discharge is performed. The operation unit 51 also functions as the period reception unit.

Subsequently, the user operates the operation unit 51 to input the number of repetitions of the selected operation. The operation unit 51 receives the input of the number of repetitions. In the example of FIG. 12, “charge→discharge” is selected, and eight is input as the number of repetitions. For this reason, the operation for performing the discharge after the charge is continuously performed eight times. When the selected operation is not repeated, the user may input one as the number of repetitions. In the example of FIG. 13, “charge (constant)” is selected, and one is input as the number of repetitions. For this reason, the charge that the charge amount is constant is not continuously repeated.

As described above, the selection of the operation and the inputs of the power, the period, and the number of repetitions of the energy storage system 6 are performed in a list.

As illustrated in FIGS. 12 and 13, the reception screen of the charge-discharge illustrates the setting period, a determined period in which the operation is determined, and an undetermined period in which the operation is not determined. The determined period is the total of periods input through the operation unit 51 in the list. The undetermined period is a remaining period of the setting period, and is calculated by subtracting the determined period from the setting period. The setting period is updated according to the content selected for the setting period. The determined period and the undetermined period are updated according to the selection of the list and the input of the content.

Subsequently, when the undetermined period exists, namely, when the undetermined period exceeds zero, the user selects whether to repeat one or the plurality of operations illustrated in the list on the reception screen of the charge-discharge for the operation in the undetermined period. The user clicks the triangle button corresponding to the repetition of the operation in the list on the reception screen of the charge-discharge. Thus, validity and invalidity are displayed as items to be selected. The user selects one of the validity and the invalidity. The operation unit 41 receives the selection whether to repeat one or the plurality of operations illustrated in the list on the reception screen of the charge-discharge.

When the invalidity is selected in the case where the undetermined period exists, one or the plurality of operations illustrated in the list are not repeated, and the user needs to determine the operation in the undetermined period. When the validity is selected in the case where the undetermined period exists, one or the plurality of operations illustrated in the list are repeated. Thus, the operation in the undetermined period is determined.

When the invalidity is selected in the case where the undetermined period exists, the user selects one operation from the plurality of types of operations related to the operation in the undetermined period by operating the operation unit 51. The plurality of types of operations are previously set. The user clicks the triangle button corresponding to the operation in the undetermined period on the reception screen of the charge-discharge. Thus, a plurality of types of operations are displayed. The user selects one operation from the plurality of displayed operations. The operation unit 51 receives the selection of one operation from the plurality of types of operations related to the operation in the undetermined period on the reception screen of the charge-discharge. Examples of the plurality of types of operations include constant current constant voltage charge, no charge-discharge, and the like. Each of the plurality of operations that can be selected as the operation in the undetermined period is different from the plurality of operations selected with respect to the operation in the list. The operation unit 51 also functions as the second selection reception unit.

The constant current constant voltage charge is performed as follows. When the terminal voltage of the energy storage apparatus 1 is low, namely, when the voltage of the terminal to which the power line W is connected is low, the constant current is supplied to the energy storage apparatus 1. When the terminal voltage of the energy storage apparatus 1 is high, the constant voltage is applied to the terminal of the energy storage apparatus 1. Accordingly, the energy storage apparatus 1 is charged.

No charge-discharge means that the charge-discharge amount of the energy storage apparatus 1 is zero.

Subsequently, the user selects one model from the first model to the third model for the energy storage system 6. The user inputs the conversion efficiency of the power conditioner 61, the conversion efficiency of the transformer 60, and the transmission efficiency of the power line W for the selected model. As described above, these are values that are greater than zero and less than or equal to one. The operation unit 51 receives the input of the conversion efficiency of the power conditioner 61, the conversion efficiency of transformer 60, and the transmission efficiency of the power line W on the reception screen of the charge-discharge. The charge amount Pc1 and the discharge amount Pc2 of the energy storage apparatus 1 are calculated based on the two conversion efficiencies and the two transmission efficiencies input through the operation unit 51. The operation unit 51 also functions as the first efficiency reception unit, the second efficiency reception unit, and the third efficiency reception unit.

When the user selects the second model or the third model, namely, when the transformer 60 is not included in the energy storage system 6, the user may input one as the conversion efficiency of the transformer 60. Accordingly, in the equations (1) and (2), one is substituted for the conversion efficiency Et, and the equations calculating the charge amount Pc1 and the discharge amount Pc2 are converted into the equations (3) and (4).

When the first model is selected, the transmission efficiency of the power line W input by the user through the operation unit 51 is the transmission efficiency of the entire two power lines W, W.

On the reception screen of the charge-discharge, the controller 53 acquires the charge-discharge data indicating both the content selected through the operation unit 51 and the content input through the operation unit 51 from the operation unit 51. The content indicated by the charge-discharge data includes the operation selected from the plurality of types of operations related to the charge-discharge in the list of the reception screen of the charge-discharge, and the charge-discharge data corresponds to the operation data.

The user operates the operation unit 51 to click the button labeled as “generation of pattern data” on the reception screen of the charge-discharge. Thus, the operation unit 51 receives the instruction to generate the pattern data. The user clicks the button labeled as “generation of pattern file” on the reception screen of the charge-discharge. Thus, the operation unit 51 receives the instruction to generate the pattern file F. The user clicks the “reset” button on the reception screen of the charge-discharge. Thus, the operation unit 51 receives a reset instruction that instructs to reset the content of the reception screen of the charge-discharge.

The user of the pattern generation apparatus 5 instructs the end of the pattern generation processing by operating the operation unit 51. The operation unit 51 receives the instruction to end the pattern generation processing. For example, the user operates the operation unit 51, and clicks an upper right button on the reception screen of the charge-discharge to instruct the end of the pattern generation processing.

As illustrated in FIG. 11, after executing step S11, the controller 53 determines whether the operation unit 51 receives the instruction to generate the pattern data (step S12). When determining that the operation unit 51 receives the instruction to generate the pattern data (YES in S12), the controller 53 generates the pattern data as illustrated in FIG. 6 based on the charge-discharge data acquired from the operation unit 51 (step S13). As described above, the charge-discharge data indicates the content selected and input on the reception screen of the charge-discharge through the operation unit 51. The controller 53 functions as the generation unit. The pattern file F including the pattern data generated by the controller 53 of the pattern generation apparatus 5 is used for predicting the life of the energy storage apparatus 1 in the life prediction apparatus 4.

As described above, the power of the energy storage system 6 indicates the charge amount or the discharge amount. The absolute value of the charge-discharge amount of the energy storage apparatus 1 is calculated by substituting the power of the energy storage system 6, the conversion efficiency of the power conditioner 61, the conversion efficiency of the transformer 60, and the transmission efficiency of the power line W into the equation (1) or (2). The equation (1) is used to calculate the charge amount. The equation (2) is used to calculate the discharge amount.

Subsequently, the controller 53 instructs the display 50 to display a graph illustrating the transition of the charge-discharge amount corresponding to the pattern data generated in step S13 (step S14). An example of the graph illustrating the transition of the charge-discharge amount is the graph in FIG. 5.

As described above, because the display 50 displays the transition of the charge-discharge amount corresponding to the pattern data generated by the controller 53, the user of the pattern generation apparatus 5 can intuitively grasp the transition of the charge-discharge amount. The display 50 also functions as the transition display.

When determining that the operation unit 51 does not receive the instruction to generate the pattern data (NO in S12) or after executing step S14, the controller 53 determines whether the operation unit 51 receives the instruction to generate the pattern file F (step S15).

When the pattern data is not generated, the operation unit 51 does not receive the instruction to generate the pattern file F.

When determining that the operation unit 51 receives the instruction to generate the pattern file F (YES in S15), the controller 53 generates the pattern file F including the latest pattern data generated in step S13 (step S16). Subsequently, the controller 53 writes the pattern file F generated in step S16 in the storage 52 (step S17). When determining that the operation unit 51 does not receive the instruction to generate the pattern file F (NO in S15), or after executing step S17, the controller 53 determines whether the operation unit 51 receives an instruction to reset the content of the reception screen of the charge-discharge (step S18).

When determining that the operation unit 51 receives the reset instruction (YES in S18), the controller 53 resets the content of the reception screen of the charge-discharge (step S19). Thus, for example, the content selected or input on the reception screen of the charge-discharge is changed as follows. The setting period, the repetition of the operation in the list, and the operation in the undetermined period are changed to previously set initial content. The input content in the list is eliminated. The conversion efficiency of the power conditioner 61, the conversion efficiency of the transformer 60, and the transmission efficiency of the power line W are changed to previously set initial values, for example, one.

When determining that the operation unit 51 does not receive the reset instruction (NO in S18), or after executing step S19, the controller 53 determines whether the operation unit 51 receives an instruction to end the pattern generation processing (step S20). When determining that the operation unit 51 does not receive the instruction to end the pattern generation processing (NO in S20), the controller 53 executes step S12 and waits until the operation unit 51 receives the end instruction. When determining that the operation unit 51 receives the instruction to end the pattern generation processing (YES in S20), the controller 53 ends the pattern generation processing.

As described above, in the pattern generation apparatus 5, the manufacturer generates the pattern data by selecting the operation from the plurality of types of operations on the reception screen of the charge-discharge of the energy storage system 6. Accordingly, the pattern data is easy to generate, and can be generated in a short time.

The configuration of the pattern generation apparatus 5 may be a configuration in which the user selects at least two of: the operation in which only the charge is performed, the operation in which only the discharge is performed, or the operation in which the charge and the discharge are continuously performed once each as the operation executed within the setting period, namely, as the operation selected in the list in FIGS. 12 and 13. In this case, because these basic operations can be selected, various pattern data can be generated in a short time by combining at least two operations as necessary.

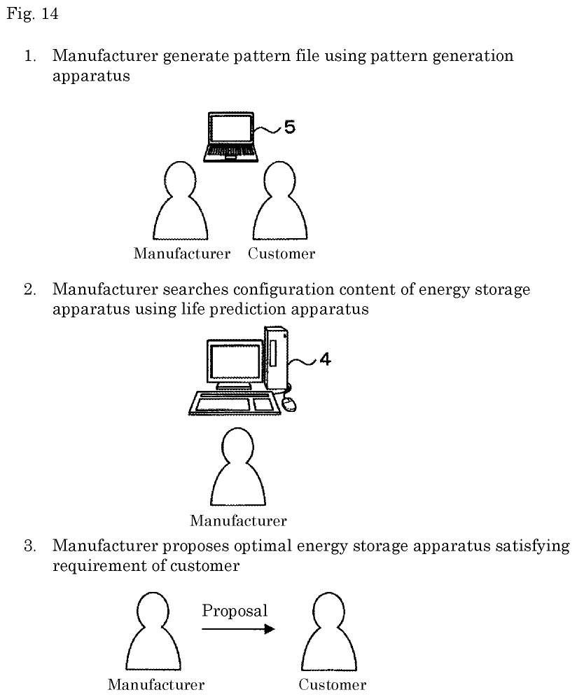

FIG. 14 is an explanatory diagram illustrating a use example of the pattern generation apparatus 5 and the life prediction apparatus 4. It is assumed that the pattern generation apparatus 5 is a portable apparatus. For example the manufacturer of the energy storage apparatus 1 visits a customer with the pattern generation apparatus 5. First the manufacturer listens to the customer about the content related to the charge-discharge of the energy storage system 6, and selects and inputs the charge-discharge related to the energy storage system 6 on the reception screen of the charge-discharge in FIGS. 12 and 13. The manufacturer causes the pattern generation apparatus 5 to display the graph of the transition of the charge-discharge amount, and quickly presents the graph to the customer.

When the customer checks the graph and the pattern data does not appropriately simulate the transition of the charge-discharge amount in the use environment, the manufacturer changes the content of the reception screen of the charge-discharge of the energy storage system 6 on the spot, and generates the pattern data indicating the transition of the charge-discharge amount reflecting the changed content. The manufacturer presents the customer again with the graph of the transition of the charge-discharge amount indicated by the generated pattern data. Because the pattern data can be generated in a short time, this series of actions can be repeated in a short time.

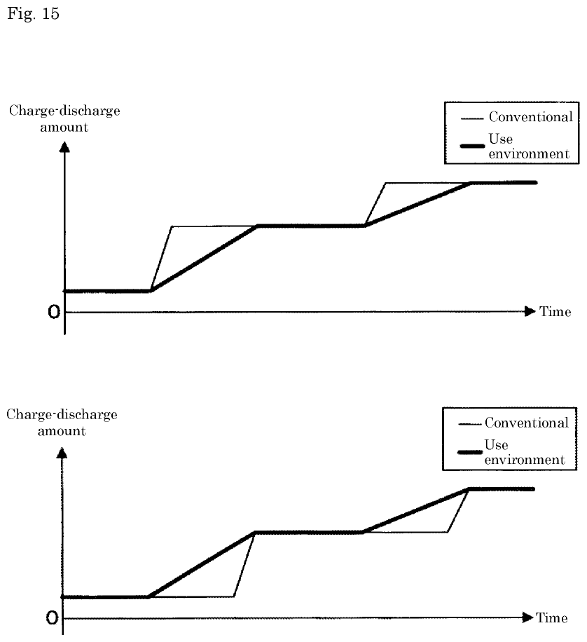

FIG. 15 is an explanatory diagram illustrating an effect of the pattern generation apparatus 5. In FIG. 15, the transition of a conventionally produced charge-discharge amount is indicated by a thin solid line. The transition of the charge-discharge amount in the use environment is indicated by a thick solid line. The portion where the two transitions overlap each other is indicated by the thick solid line. Conventionally, the manufacturer receives rough information or operation information in the energy storage system similar to the energy storage system scheduled to be ordered from the customer, returns to own company, and produces the pattern data indicating the transition of the charge-discharge amount of the energy storage apparatus within the setting period based on the rough information or the operation information.

As illustrated in the upper side of FIG. 15, there is a possibility that the manufacturer produces the pattern data set to excessively charge and discharge the energy storage apparatus as compared with the charge-discharge in the actual use environment. When the configuration content of the energy storage apparatus 1 is determined based on the pattern file F including the pattern data, the energy storage apparatus 1 having the excessive configuration and the high price is proposed compared with the optimal energy storage apparatus satisfying the requirement of the customer. In this case, there is a high possibility that the manufacturer loses a business opportunity (fails to receive an order).

As illustrated in the lower side of FIG. 15, there is a possibility that the manufacturer produces the pattern data set to excessively charge and discharge the energy storage apparatus as compared with the charge-discharge in the actual use environment. When the configuration content of the energy storage apparatus 1 is determined based on the pattern file F including the pattern data, the energy storage apparatus 1 having an excessively small configuration and a low price is proposed as compared with the optimal energy storage apparatus satisfying the requirement of the customer. In this case, after the energy storage system 6 including the energy storage apparatus 1 is delivered, there is a high possibility that the requirement of the customer will not be satisfied earlier than the expectation based on the life prediction.

When the pattern generation apparatus 5 is used, as described above, the manufacturer can repeat a series of actions from the selection and input related to the charge-discharge of the energy storage system 6 to the presentation of the transition of the charge-discharge amount on the reception screen of the charge-discharge for a short time. As a result, the manufacturer can generate the pattern file F including the pattern data indicating the transition of the charge-discharge amount appropriately simulating the transition of the charge-discharge amount in the use environment, namely, the transition of the charge-discharge amount indicated by the solid line in FIG. 15 at a negotiation site with the customer, and can agree on the pattern data with the customer.

As illustrated in FIG. 14, after generating the pattern file F using the pattern generation apparatus 5, the manufacturer returns to own company and, for example, considers various configuration contents of the energy storage apparatus 1 satisfying the requirement of the customer for the life based on the pattern data included in the generated pattern file F. The manufacturer stores the pattern file F generated by the pattern generation apparatus 5 in the storage 42 of the life prediction apparatus 4. The manufacturer instructs the life prediction apparatus 4 to execute the life prediction processing by operating the operation unit 41. The manufacturer causes the life prediction apparatus 4 to predict the lives of various energy storage apparatuses 1 having different configuration contents based on the pattern data included in the generated pattern file F. Thus, the manufacturer can investigate the configuration content of the energy storage apparatus 1 which satisfies the requirement of the customer with respect to the life.

Finally, the manufacturer proposes the optimal energy storage apparatus 1 that satisfies the requirement of the customer to the customer.

The charge amount and the discharge amount of the energy storage system 6, the conversion efficiency of the power conditioner 61, the transmission efficiency of the power line W, the conversion efficiency of the transformer 60, and the period during which the charge or the discharge is performed are considered in the generation of the pattern data performed by the pattern generation apparatus 5. For this reason, the pattern generation apparatus 5 can generate the pattern data that more appropriately simulates the transition of the charge-discharge amount in the use environment.

On the reception screen of the charge-discharge, it is sufficient to select the operation from the plurality of types of operations even for the operation in the undetermined period, so that the generation of the pattern data is further facilitated.

### Second Embodiment

Sometimes the manufacturer of the energy storage apparatus receives the pattern data indicating the transition of the charge-discharge power within a predetermined period such as one day, one month, or one year from the customer at the negotiation site.

The manufacturer predicts the lives of various energy storage apparatuses having different configuration contents based on the pattern data received from the customer. Based on the predicted result, the manufacturer proposes the reasonable energy storage apparatus that satisfies the life required by the customer to the customer. The manufacturer predicts the life of the energy storage apparatus by causing an information processing apparatus, for example, a personal computer to execute processing.

Sometimes a format of the pattern data received from the customer is not suitable for the life prediction processing for predicting the life. In this case, the manufacturer edits the pattern data received from the customer using, for example, spreadsheet software, and generates the pattern data used in the life prediction processing. The number of operations performed by the manufacturer to edit the pattern data is large, and much time is spent in editing the pattern data. The manufacturer returns from the negotiation site to own company, edits the pattern data, and determines the configuration content of the energy storage apparatus satisfying the life required by the customer based on the edited pattern data.

When the edited pattern data is different from the pattern data assumed by the customer, the manufacturer needs to return to own company again and edit the pattern data.

The second embodiment provides a generation apparatus, a generation method, and the like that automatically edit and generate the pattern data.

The generation apparatus includes: an information acquisition unit that acquires the editing information used for editing first pattern data indicating the transition of the charge-discharge power of the energy storage apparatus within a predetermined period; and an editing generation unit that edits the first pattern data based on the editing information acquired by the information acquisition unit to generate second pattern data used for the prediction of the degradation of the energy storage apparatus and indicating the transition of the charge-discharge power of the energy storage apparatus within the predetermined period.

For example, the user of the generation apparatus inputs the editing information used for editing the first pattern data. The generation apparatus acquires the editing information input by the user, automatically edits the first pattern data based on the acquired editing information, and generates the second pattern data. When an editing processing speed is high, the second pattern data can be immediately generated. In this case, the user (for example, the manufacturer of the energy storage apparatus) can display the transition of the charge-discharge power indicated by the second pattern data at the negotiation site, and request the customer to check the second pattern data. When the second pattern data is different from the pattern data assumed by the customer, the user may change the editing information and edit the first pattern data again at the negotiation site.

The generation apparatus may include: an instruction reception unit that receives a combination instruction of a plurality of pieces of transition data indicating transition of charge-discharge power related to the energy storage apparatus; and a combination generation unit that generates the first pattern data by sequentially combining the plurality of pieces of transition indicated by the plurality of pieces of transition data when the instruction receiver receives the combination instruction.

When the plurality of pieces of transition data constituting the first pattern data are provided from the customer, the user gives a combining instruction. Thus, the plurality of pieces of transition data are combined to generate the first pattern data.

In the generation apparatus, the first pattern data and the second pattern data may be data in which a plurality of charge-discharge power values are listed for each unit time. The information acquisition unit may acquire a first unit time and a second unit time corresponding to the first pattern data and the second pattern data. The editing generation unit may generate the second pattern data in which the plurality of charge-discharge power values are listed for each second unit time acquired by the information acquisition unit based on the first unit time and the second unit time acquired by the information acquisition unit.

The user may check the first unit time of the first pattern data and determine the second unit time of the second pattern data generated using the first pattern data. For example, the user inputs the checked first unit time and the determined second unit time. The generation apparatus acquires the first unit time and the second unit time input by the user, and generates the desired second pattern data in which the plurality of charge-discharge power values are listed every second unit time based on the acquired first unit time and second unit time.

In the generation apparatus, when the first unit time acquired by the information acquisition unit is shorter than the second unit time acquired by the information acquisition unit, the editing generation unit may thin out one or the plurality of charge-discharge power values from the plurality of charge-discharge power values indicated by the first pattern data.

When the first unit time is shorter than the second unit time, namely, when the number of charge-discharge power values indicated by the first pattern data is large, the generation apparatus thins out one or the plurality of charge-discharge power values from the plurality of charge-discharge power values indicated by the first pattern data. Thus, the second pattern data is generated.

When the first unit time acquired by the information acquisition unit is longer than the second unit time acquired by the information acquisition unit, the editing generation unit may perform interpolation by adding one or the plurality of charge-discharge power values to the plurality of charge-discharge power values indicated by the first pattern data.

When the first unit time is longer than the second unit time, namely, when the number of charge-discharge power values indicated by the first pattern data is small, the generation apparatus performs the interpolation by adding one or the plurality of charge-discharge power values to the plurality of charge-discharge power values indicated by the first pattern data. Thus, the second pattern data is generated.

When the charge-discharge power related to the energy storage apparatus is charge-discharge power of the energy storage system in which the energy storage apparatus is charged or discharged through an electric component, the information acquisition unit may acquire the efficiency related to the power of the electric component. The editing generation unit may edit the first pattern data to change the plurality of charge-discharge power values indicated by the first pattern data based on the efficiency acquired by the information acquisition unit.

In the case where the pattern data indicating the transition of the charge-discharge power within a predetermined period is provided from a customer, when the provided pattern data is the first pattern data, the user inputs the efficiency related to the electric component such as the power line, the transformer, or the voltage converter used in the energy storage system. The generator acquires the efficiency input by the user, and changes the charge-discharge power value indicated by the first pattern data to the charge-discharge power value of the energy storage apparatus based on the acquired efficiency.

The information acquisition unit acquires a multiplication value of the power efficiency in the plurality of electric components when the number of the electric components is at least two, and acquires the power efficiency in the electric components when the number of the electric components is one.

The efficiency is a numerical value that exceeds zero and is less than or equal to one. When the number of electric components included in the energy storage system is at least two, the user inputs the multiplication value of the efficiencies of the plurality of electric components. When the number of electric components included in the energy storage system is one, the user inputs the efficiency of the electric power of the electric component. The generator acquires the efficiency input by the user, and changes the charge-discharge power value indicated by the first pattern data to the charge-discharge power value of the energy storage apparatus based on the acquired efficiency.

In the generation apparatus, the plurality of charge-discharge power values may be listed in the first pattern data. The editing generation unit may multiply the charge-discharge power value indicating the charge among the plurality of charge-discharge power values indicated by the first pattern data by the efficiency acquired by the information acquisition unit, or may divide the charge-discharge power value indicating the discharge among the plurality of charge-discharge power values indicated by the first pattern data by the efficiency acquired by the information acquisition unit.

The generation apparatus calculates the charge-discharge power value of the energy storage apparatus indicating the charge by multiplying the charge-discharge power value indicating the charge by the efficiency. The generation apparatus calculates the charge-discharge power value of the energy storage apparatus indicating the discharge by dividing the efficiency by the charge-discharge power value indicating the discharge.

The generation apparatus may include a transition display that displays the transition of the charge-discharge power indicated by the second pattern data generated by the editing generation unit.

The generation apparatus displays the transition of the charge-discharge power indicated by the second pattern data generated by the editing. Thus, the transition of the charge-discharge power indicated by the second pattern data can be easily understood.

The plurality of charge-discharge power values may be listed in the second pattern data. The generation apparatus may include a charge ratio calculator that calculates a plurality of charging ratios occupied by charge-discharge power values belonging to each of a plurality of charge ranges related to the charge power among the plurality of charge-discharge power values indicated by the second pattern data generated by the editing generation unit and indicating the charge.

The plurality of charge-discharge power values indicated by the second pattern data include the plurality of charge-discharge power values indicating the charge and the plurality of charge-discharge power values indicating the discharge. A proportion of the charge-discharge power value belonging to each charge range in all the charge-discharge power values indicating the charge is calculated. For example, when the plurality of ratios corresponding to the plurality of charge ranges is displayed, a tendency related to the charge can be easily understood.

The plurality of charge-discharge power values may be listed in the second pattern data. The generation apparatus may include a discharge ratio calculator that calculates a plurality of discharging ratios occupied by charge-discharge power values belonging to each of a plurality of discharge ranges related to the discharge power among the plurality of charge-discharge power values indicated by the second pattern data generated by the editing generation unit and indicating the discharge.

As described above, the plurality of charge-discharge power values indicated by the second pattern data include the plurality of charge-discharge power values indicating the charge and the plurality of charge-discharge power values indicating the discharge. A proportion of the charge-discharge power value belonging to each discharge range in all the charge-discharge power values indicating the discharge is calculated. For example, when the plurality of ratios corresponding to the plurality of discharge ranges is displayed, a tendency related to the discharge can be easily understood.

The generation apparatus may include a content acquisition unit that acquires a configuration content of the energy storage apparatus, and a prediction unit that predicts degradation of the energy storage apparatus based on the second pattern data generated by the editing generation unit and the configuration content acquired by the content acquisition unit.

For example, the user inputs the configuration content of the energy storage apparatus 1. The generation apparatus acquires the configuration content of the energy storage apparatus input by the user, and predicts the degradation of the energy storage apparatus using the acquired configuration content and the second pattern data generated by the editing.

The prediction unit may predict a period until the capacity of the energy storage apparatus decreases to a predetermined value as the prediction of the degradation of the energy storage apparatus.

The prediction of the degradation of the energy storage apparatus may be the prediction of the period until the capacity of the energy storage apparatus decreases to the predetermined value.

In the generation method, a computer executes processing of acquiring editing information used for editing first pattern data indicating the transition of the charge-discharge power of the energy storage apparatus within a predetermined period, and editing the first pattern data based on the acquired editing information to generate second pattern data used for prediction of degradation of the energy storage apparatus and indicating the transition of the charge-discharge power of the energy storage apparatus within the predetermined period.

The computer program causes a computer to execute processing of acquiring editing information used for editing first pattern data indicating transition of charge-discharge power of the energy storage apparatus within a predetermined period, and editing the first pattern data based on the acquired editing information to generate second pattern data used for prediction of degradation of the energy storage apparatus and indicating the transition of the charge-discharge power of the energy storage apparatus within the predetermined period.

Hereinafter, the efficiency of the energy storage system 6 is referred to as system efficiency. In the first model of the energy storage system 6, the system efficiency is represented by Et·Ec·Ew. In each of the second model and the third model of the energy storage system 6, the system efficiency is represented by Ec·Ew. When the system efficiency is described as Es, the charge power value Pc1 and the discharge power value Pc2 of the energy storage apparatus 1 are expressed by the following equations (5) and (6), respectively.

$$\begin{matrix}P c 1 = P s 1 \cdot E s & ( 5 ) \\ P c 2 = P s2 / E s & ( 6 )\end{matrix}$$

As illustrated in the equation (5), the charge power value Pc1, namely, the charge-discharge power value of the energy storage apparatus 1 indicating the charge is calculated by multiplying the charge power value Ps1, namely, the charge-discharge power value of the energy storage system 6 indicating the charge by the system efficiency. As illustrated in the equation (6), the discharge power value Pc2, namely, the charge-discharge power value of energy storage apparatus 1 indicating the discharge is calculated by dividing the discharge power value Ps2, namely, the charge-discharge power value of the energy storage system 6 indicating the discharge by the system efficiency.

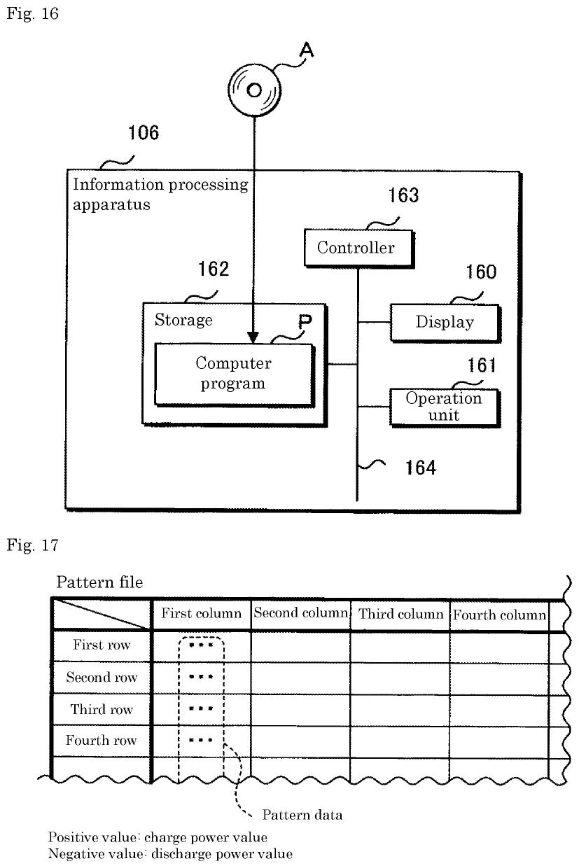

FIG. 16 is a block diagram illustrating a configuration of an information processing apparatus 106. Examples of the information processing apparatus 106 include a portable personal computer and a portable tablet. The information processing apparatus 106 includes a display 160, an operation unit 161, a storage 162, and a controller 163. These are connected to an internal bus 164.

The display 160 displays various screens according to an instruction of the controller 163. The operation unit 161 includes a touch panel, a keyboard, and a mouse. The operation unit 161 is operated by the user of the information processing apparatus 106, and receives various inputs and selections from the user.

The storage 162 is a nonvolatile memory. The storage 162 stores the computer program P. The controller 163 includes a processing device, for example, a CPU. The processing device (computer) of the controller 163 executes the computer program P to execute acquisition processing, content output processing, editing processing, transition display processing, distribution display processing, life prediction processing, and the like.

The information processing apparatus 106 edits the first pattern data indicating the transition of the charge-discharge power of the energy storage apparatus 1 within the predetermined period, thereby generating the second pattern data indicating the transition of the charge-discharge power of the energy storage apparatus 1 within the predetermined period. The second pattern data is used for the prediction of degradation of the energy storage apparatus 1, specifically, the prediction of the life of the energy storage apparatus 1. The information processing apparatus 106 also displays various graphs related to the second pattern data.

The acquisition processing is processing for acquiring an editing content related to the editing of the first pattern data and the graph content related to the graph. Each of the editing content and the graph content is data (information). The editing content includes the editing information used for the editing. The graph content includes the graph information used for generating the graph. The content output processing is processing for generating a content file indicating the editing content. The editing processing is processing for editing the first pattern data based on the editing content acquired in the acquisition processing.

The transition display processing is processing for displaying the transition of the charge-discharge power indicated by the second pattern data based on the graph content acquired in the acquisition processing. The distribution display processing is processing for displaying an output distribution indicating a ratio of the charge-discharge power values belonging to a plurality of positive value ranges and a ratio of the charge-discharge power values belonging to a plurality of negative value ranges based on the graph content acquired in the acquisition processing. The negative value range is a range to which the absolute value of the negative value belongs. The life prediction processing is processing for predicting the life of the energy storage apparatus 1 based on the plurality of charge-discharge power values indicated by the second pattern data. The information processing apparatus 106 functions as the generation apparatus.

The computer program P may be stored in a storage medium A readable by the processing device included in the controller 163. In this case, the computer program P read from the storage medium A by a read apparatus (not illustrated) is written in the storage 162. The storage medium A is an optical disk, a flexible disk, a magnetic disk, a magneto-optical disk, a semiconductor memory, or the like. The optical disk is a compact disc (CD)-read only memory (ROM), a digital versatile disc (DVD)-ROM, a BD (Blu-ray (registered trademark) disc), or the like. For example, the magnetic disk is a hard disk. The computer program P may be downloaded from an apparatus (not illustrated) connected to a communication network (not illustrated), and the downloaded computer program P may be written in the storage 162.

The number of processing devices included in the controller 163 is not limited to one, and may be at least two. In this case, the plurality of processing devices may execute the acquisition processing, the content output processing, the edit processing, the transition display processing, the distribution display processing, the life prediction processing, and the like according to the computer program P.

The first pattern data and the second pattern data are data in which the plurality of charge-discharge power values are listed for each unit time. Hereinafter, the data in which the plurality of charge-discharge power values are listed for each unit time is referred to as the pattern data. The pattern data such as the first pattern data or the second pattern data is included in the pattern file. The unit time of each of the first pattern data and the second pattern data corresponds to the first unit time and the second unit time.

FIG. 17 is an explanatory view of the pattern file. As illustrated in FIG. 17, in the pattern file, a plurality of cells are arranged in a matrix shape. A numerical value is input to each of the plurality of cells. The arrangement of each cell is indicated by a combination of a row number and a column number. In the example of FIG. 17, the pattern data is illustrated in the first column. A charge-discharge power value is indicated for each of the plurality of cells belonging to the first column. A positive value indicates a charge power value. A negative value indicates a discharge power value. The plurality of charge-discharge power values are sequentially input from the upper cell. The time interval between two charge-discharge power values adjacent to each other in the vertical direction is the unit time described above. For example, the unit time is one second. The pattern file may include data other than the pattern data.

In the pattern file, the pattern data is indicated in one column or one row. An example in which the pattern data is displayed in one column in the pattern file as illustrated in FIG. 17 will be described below.

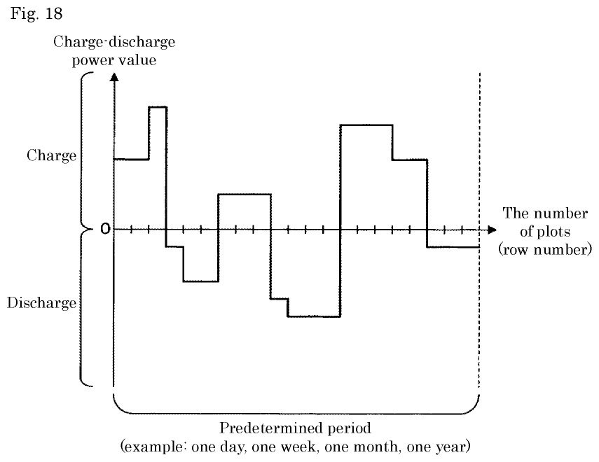

FIG. 18 is a graph illustrating the transition of the charge-discharge power. For example, FIG. 18 illustrates the plurality of charge-discharge power values input in the first column of the pattern file in FIG. 17. In the example of FIG. 18, the positive value and the negative value indicate the charge and the discharge, respectively. The horizontal axis represents the number of plots, namely, the row number. The charge-discharge power values corresponding to a plurality of rows are sequentially illustrated from the charge-discharge power value corresponding to the first row. The horizontal axis corresponds to a time axis indicating an elapsed time. One scale on the horizontal axis corresponds to the unit time. It is assumed that there is no variation in the charge-discharge power value during the period of one scale. The pattern data indicates the transition of the charge-discharge power within a predetermined period. Examples of the predetermined period include one day, one week, one month, and one year.

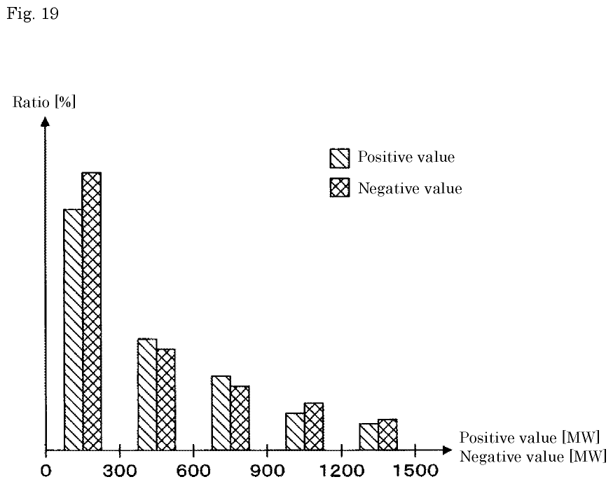

FIG. 19 is a graph illustrating an output distribution. The plurality of charge-discharge power values indicated by the pattern data include the plurality of charge-discharge power values indicating the charge, namely, the charge power value, and the plurality of charge-discharge power values indicating the discharge, namely, the discharge power value. Each of the charge power value and the discharge power value is indicated by the positive value or the negative value. In the pattern data of FIG. 17, the charge power value is indicated by the positive value, and the discharge power value is indicated by the negative value. The output distribution indicates the ratio by all positive values.

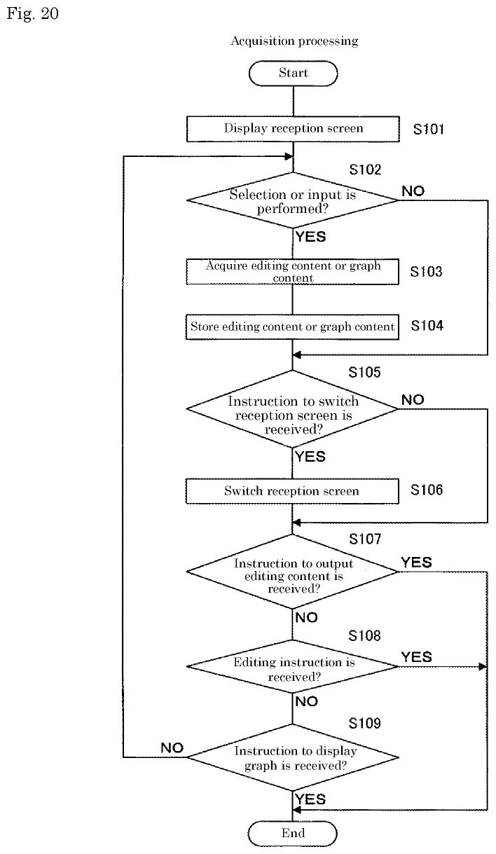

The acquisition processing for acquiring the editing content and the graph content will be described. FIG. 20 is a flowchart illustrating the procedure of the acquisition processing. The user of the information processing apparatus 106 instructs the execution of the acquisition processing by operating the operation unit 161. When the operation unit 161 receives the instruction to execute the acquisition processing, the controller 163 executes the acquisition processing. In the acquisition processing, first the controller 163 instructs the display 160 to display the reception screen that receives the editing content or the graph content (step S101).

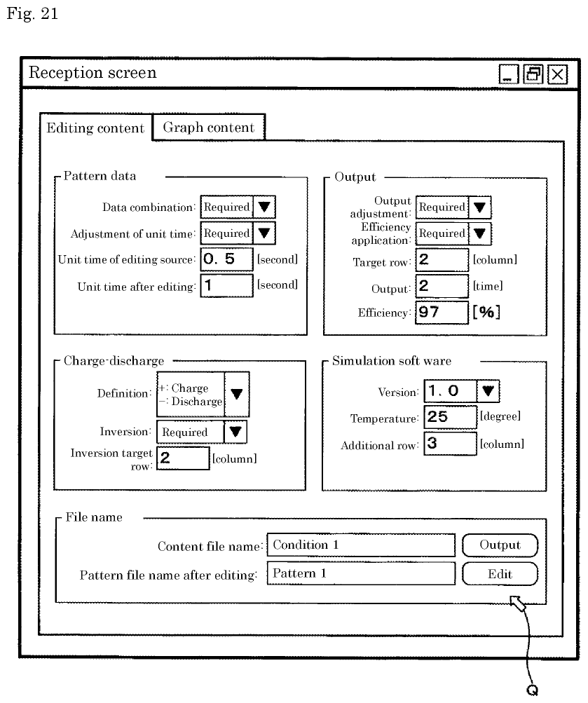

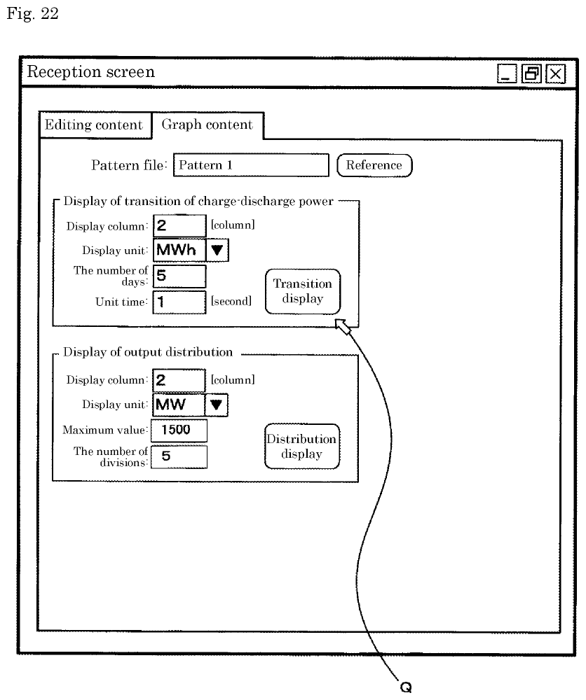

FIG. 21 is a schematic diagram illustrating the reception screen that receives the editing content. FIG. 22 is a schematic diagram illustrating the reception screen that receives the graph content. For example, the user moves a pointer Q on the reception screen by operating the mouse included in the operation unit 161, and selects the editing content and the graph content by clicking. For example, the user inputs the editing content and the graph content by operating the keyboard included in the operation unit 161.

The user selects whether adjustment of the unit time is required, inputs the unit time of the pattern data (first pattern data) of an editing source, and the like. Thus, the controller 163 acquires the editing content selected or input by the user. The user selects a unit used for displaying the graph, or inputs the number of days (predetermined period) indicated by the pattern data. Thus, the controller 163 acquires the graph content selected or input by the user. The item of the editing content and the graph content will be described later.

When the user presses an output button using the operation unit 161 on the reception screen of the editing content in FIG. 21, the controller 163 receives an instruction to output the editing content. When the user presses an edit button using the operation unit 161, the controller 163 receives an editing instruction. When the user selects a tab describing “graph content” using the operation unit 161, the controller 163 receives an instruction to switch from the reception screen of the editing content to the reception screen of the graph content.

When the user presses a transition display button or a distribution display button using the operation unit 161 on the reception screen of the graph content in FIG. 22, the controller 163 receives a graph display instruction. The storage 162 stores one or a plurality of pattern files. When the user presses a reference button using the operation unit 161, the user can select the pattern file stored in the storage 162. When the user selects the tab labeled with “editing matter” using the operation unit 161, the controller 163 receives an instruction to switch the reception screen of the graph content to the reception screen of the editing content.

As illustrated in FIG. 20, after executing step S101, the controller 163 determines whether the selection or input related to the editing content or the graph content is performed by the user (step S102). When determining that the selection or input is performed (YES in S102), the controller 163 acquires the editing content or graph content selected or input by the user (step S103), and stores the acquired editing content or graph content in the storage 162 (step S104). The controller 163 functions as the information acquisition unit.

When determining that the selection or input is not performed (NO in S102), or after executing step S104, the controller 163 determines whether the instruction to switch the reception screen is received (step S105). When determining that the instruction to switch the reception screen is received (YES in S105), the controller 163 instructs the display 160 to switch the reception screen to the reception screen of the editing content or the graph content (step S106). In step S106, when the user selects the tab of the editing content, the controller 163 instructs switching to the reception screen of the editing content. When the user selects the tab of the graph content, the controller 163 instructs switching to the reception screen of the graph content.

When determining that the instruction to switching to the reception screen is not received (NO in S105), or after executing step S106, the controller 163 determines whether the instruction to output the editing content is received (step S107). When determining that the instruction to output the editing content is received (YES in S107), the controller 163 ends the acquisition processing and executes the content output processing.

When determining that the instruction to output the editing content is not received (NO in S107), the controller 163 determines whether the instruction to output the editing content is received (step S108). When determining that the editing instruction is received (YES in S108), the controller 163 ends the acquisition processing and executes the editing processing. When determining that the editing instruction is not received (NO in S108), the controller 163 determines whether the instruction to display the graph is received (step S109).

When determining that the instruction to display the graph is received (YES in S109), the controller 163 ends the acquisition processing, and executes the transition display processing or the distribution display processing. When the user presses the transition display button, the controller 163 executes the transition display processing. When the user presses the distribution display button, the controller 163 executes distribution display processing. When determining that the instruction to display the graph is not received (NO in S109), the controller 163 executes step S102.

As described above, in the acquisition processing, the controller 163 repeatedly executes the acquisition of the editing content or the graph content or the switching of the reception screen until the instruction to output the editing content, the editing instruction, or the instruction to display the graph is received.

The editing content item in FIG. 21 and the graph content item in FIG. 22 will be described. Sometimes the first pattern data indicating the transition of the charge-discharge power related to the energy storage apparatus 1 within the predetermined period is constituted by the plurality of pieces of transition data indicating the transition of the charge-discharge power related to the energy storage apparatus 1. The period of the transition indicated by the transition data is shorter than the predetermined period. For example, when the predetermined period is one day, the first pattern data is constituted by twenty-four pieces of transition data indicating the transition of the charge-discharge power within one hour. The transition data is included in the transition file. The transition file and the transition data are indicated in the same manner as the pattern file and the pattern data. Accordingly, in the transition file, the numerical value is input to each of a plurality of cells arranged in a matrix shape, and for example, the transition data is indicated in the first column.

In the item of the data combination of FIG. 21, the user selects whether the combination of the plurality of pieces of transition data is required. In the example of FIG. 21, the requirement is selected for combining the transition data. In the item of the adjustment of the unit time, the user selects whether the adjustment of the unit time is required. When the unit time of the first pattern data is different from the unit time of the second pattern data generated by the editing, the adjustment of the unit time is required. When the unit times of the first pattern data and the second pattern data coincide with each other, the “no requirement” is selected for the adjustment of the unit time. In the example of FIG. 21, the “requirement” is selected for the adjustment of the unit time.

When the user selects the requirement for the adjustment of the unit time, the user inputs the unit time of the editing source, namely, the unit time of the first pattern data, and the unit time after the editing, namely, the unit time of the second pattern data. In the example of FIG. 21, 0.5 seconds are input as the unit time of the editing source, and one second is input as the unit time after the editing. This indicates that the number of charge-discharge power indicated by the first pattern data is large.

In the item of the output adjustment, the user selects whether the output adjustment is required. As a first example, in the case where the plurality of charge-discharge power values indicated by the first pattern data are the plurality of charge-discharge power values corresponding to one energy storage apparatus 1, the output adjustment is required when the number of energy storage apparatuses 1 included in the energy storage system 6 is at least two. As a second example, in the case where the charge-discharge power value of the energy storage apparatus 1 is changed to U times with no change of the number of energy storage apparatuses 1, the output adjustment is required when the transition of the charge-discharge power and the output distribution are checked. U is a positive real number such as two or (⅓). For the output adjustment, when the change of the plurality of charge-discharge power values indicated by the first pattern data is not required, the user selects the “no requirement”. In the item of the efficiency application, the user selects whether the efficiency application of the electric components such as the transformer 60, the power conditioner 61, or the power line W is required. When the plurality of charge-discharge power values indicated by the first pattern data, namely, the charge-discharge power value related to the energy storage apparatus 1 is the charge-discharge power value of the energy storage system 6, the efficiency application is required. When the plurality of charge-discharge power values indicated by the first pattern data are charge-discharge power values of the energy storage apparatus 1, the efficiency application is not required.

When selecting the requirement for at least one of the output adjustment or the efficiency application, the user inputs the number of the column in which the first pattern data is indicated as the target column in the first pattern file. In the example of FIG. 21, two is selected as the column number. When selecting the requirement for the output adjustment, the user inputs a multiple relating to the plurality of charge-discharge power values indicated by the first pattern data in the item of the output. In the example of FIG. 21, two is input as the multiple.

When selecting the requirement of the efficiency application, the user inputs the efficiency related to the electric power of the electric component in the item of the efficiency application. When the number of electric components included in the energy storage system 4 is one, the user inputs the efficiency related to the power of one electric component as efficiency related to the power of the electric component. When the number of electric components included in the energy storage system 6 is at least two, the efficiency related to the power in the plurality of entire electric components, namely, a multiplication value of the efficiency related to the power in the plurality of electric components is input as the efficiency related to the power of the electric component. In the example of FIG. 21, 97% is input as the efficiency. In the example of FIG. 21, the controller 163 of the information processing apparatus 106 multiplies each of the plurality of charge-discharge power values indicated in the second column of the first pattern file by two, and multiplies each of the plurality of multiplied charge-discharge power values by 0.97. Thus, the editing related to the absolute value of the numerical value is completed.

In the item of the definition, the user selects meanings indicated by positive values and negative values for the plurality of charge-discharge power values indicated by the definition, namely, the second pattern data generated by the editing. “+” indicates a positive value. “−” indicates a negative value. The option includes the combinations in which the positive value and the negative value indicate the charge and the discharge, respectively, and the combinations in which the positive value and the negative value indicate the discharge and the charge, respectively. The combination in which each of the positive value and the negative value indicates the charge and the discharge is selected in the example of FIG. 21. In the item of the reversal, the user selects whether the reversal of the positive value and the negative value is required. The option is the requirement and the no requirement. The requirement is selected in the example of FIG. 21.

In the item of the reversal target column, the user inputs the number of the column in which the first pattern data is indicated in the first pattern file. In the example of FIG. 21, two is input as the column number. In the example of FIG. 21, the controller 163 of the information processing apparatus 106 converts the positive value and the negative value into the negative value and the positive value, respectively, for the plurality of charge-discharge power values indicated in the second column of the first pattern file. Thus, the editing related to the sign of the numerical value is completed.

In FIG. 21, the editing content input or selected with respect to the items of the unit time of the editing source, the unit time after the editing, the target column, the output, the efficiency, the definition, and the reversal target column is editing information used for editing the first pattern data.

As described above, the controller 163 of the information processing apparatus 106 executes the life prediction processing according to the computer program P. The simulation software is a computer program used for the life prediction processing, and is included in the computer program P. In the item of version, the user selects the version of the simulation software. In the example of FIG. 21, 1.0 is selected as the version. Depending on the version of the simulation software, sometimes the temperature in the energy storage apparatus 1 is required as information predicting the life of the energy storage apparatus 1. When the temperature in the energy storage apparatus 1 needs to be input, the user inputs the temperature in the energy storage apparatus 1. In the example of FIG. 21, 25 degrees are input. In the additional column, the user inputs the number of the column inputting the temperature in editing the first pattern file. In the column of FIG. 21, “25” is input in the third column.

As described above, the controller 163 of the information processing apparatus 106 executes the content output processing for generating a content file indicating the editing content. In the item of the content file name, the user inputs the name of the content file. In the example of FIG. 21, “condition 1” is input as the content file name. In the item of the pattern file name after the editing, the user inputs the name of a second pattern file. In the example of FIG. 21, “pattern 1” is input as the pattern file name after the editing.

In the item of the pattern file of FIG. 22, the user selects the second pattern file stored in the storage 162. For example, the user operates the mouse included in the operation unit 161 to move the pointer Q on the reception screen, and presses the reference button. Thus, a folder including the pattern file is displayed. The user selects one of the pattern files included in the folder as the second pattern file. In the example of FIG. 22, the second pattern file having the file name of “pattern 1” is selected. When the pattern file is blank, for example, the latest second pattern file generated by the controller 163 is selected.

In the item of the display column, the number of the column in which the second pattern data is indicated in the second pattern file is input with respect to the display of the transition of the charge-discharge power (see FIG. 18). In the example of FIG. 22, two is input as the column number.

As described above, the controller 63 executes the processing for displaying the transition of the charge-discharge power indicated by the second pattern data. When the transition of the charge-discharge power is displayed, various power amounts are also displayed. In the item of the display unit related to the display of the transition of the charge-discharge power, the unit of the power amount to be displayed is selected. The options include kWh (kilowatt hour), MWh (megawatt hour) and GWh (gigawatt hour). In the example of FIG. 22, MWh is selected.

The unit of the plurality of charge-discharge power values indicated by the second pattern data is kW (kilowatts). The unit of the plurality of charge-discharge power values indicated by the second pattern data is changed to the unit selected in the item of the display unit by dividing the plurality of charge-discharge power values indicated by the second pattern data by various values. For example, the unit of the charge-discharge power value indicated by the second pattern data is changed to MW (megawatt) by dividing each of the plurality of charge-discharge power values indicated by the second pattern data by 1000. In the transition of the charge-discharge power indicated by the second pattern data, the unit of the charge-discharge power value is changed to the unit corresponding to the unit selected in the item of the display unit. For example, when the unit selected in the item of the display unit is MWh, the unit of the charge-discharge power value to be displayed is MW.

As described above, the second pattern data indicates the transition of the charge-discharge power within the predetermined period. In the item of the number of days, the user inputs the number of days corresponding to the predetermined period. When the predetermined period is one year, the user inputs 365 as the number of days. In the item of the unit time, the controller 163 inputs the unit time of the second pattern data. In the example of FIG. 22, one second is input as the unit time.

In the item of the display column, the number of the column indicating the second pattern data in the second pattern file is input with respect to the display of the output distribution (see FIG. 19). In the example of FIG. 22, two is input as the column number.

As described above, the controller 163 executes the processing for displaying the output distribution indicating the ratio of the charge-discharge power values belonging to the plurality of positive value ranges and the ratio of the charge-discharge power values belonging to the plurality of negative value ranges. The unit of the charge-discharge power value to be displayed is selected in the item of the display unit related to the display of the output distribution. The option is kW, MW, GW, and the like. MW is selected in the example of FIG. 22. As described above, the unit of the plurality of charge-discharge power values indicated by the second pattern data is kW. The controller 163 divides the plurality of charge-discharge power values indicated by the second pattern data by various numerical values to change the unit of the plurality of charge-discharge power values indicated by the second pattern data to the unit selected in the item of the display unit.

In the item of the maximum value, the user inputs the maximum value of the absolute values of the plurality of charge-discharge power values indicated by the second pattern data. In the example of FIG. 22, 1500 is input as the maximum value. When the maximum value field is blank, the maximum value of the absolute values of the plurality of charge-discharge power values indicated by the second pattern data is applied. The number of divisions is the number in the positive value range and also the number in the negative value range. In the item of the number of divisions, the user inputs the desired number of divisions. In the example of FIG. 22, 5 is input as the division number. In the example of FIG. 22, because 1500 [MW] is input as the maximum value and 5 is input as the number of divisions, as illustrated in FIG. 19, a range of 0 to 300 [MW], a range of 300 to 600 [MW], and the like are set as the plurality of positive value ranges. The plurality of negative value ranges are the same as the plurality of positive value ranges.

The content output processing will be described. As described above, the controller 163 of the information processing apparatus 106 executes the content output processing when the instruction to output the editing content is received, namely, when the output button in FIG. 21 is pressed. In the content output processing, the controller 163 generates, in the storage 162, the content file in which the file name is a name input in the item of the content file name. The content file indicates the editing content displayed on the reception screen. After generating the content file, the controller 163 ends the content output processing.

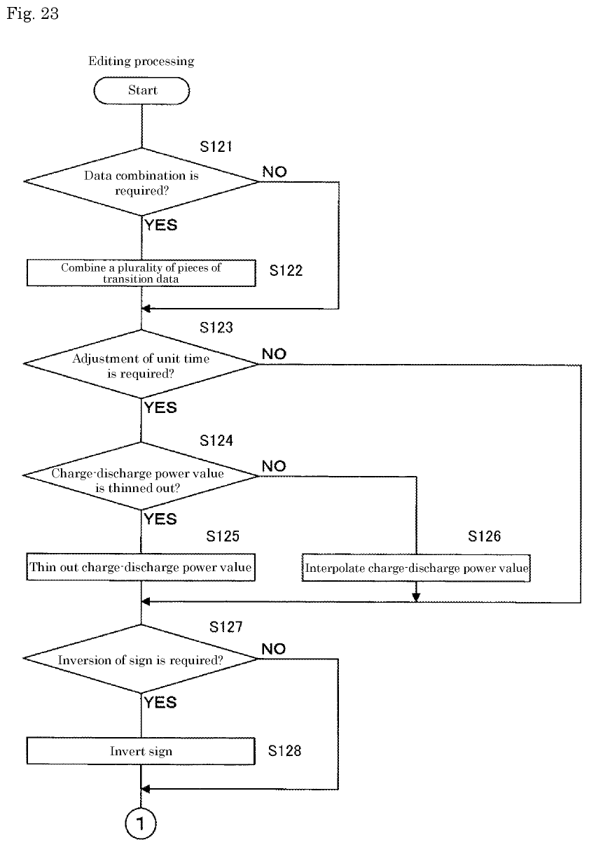

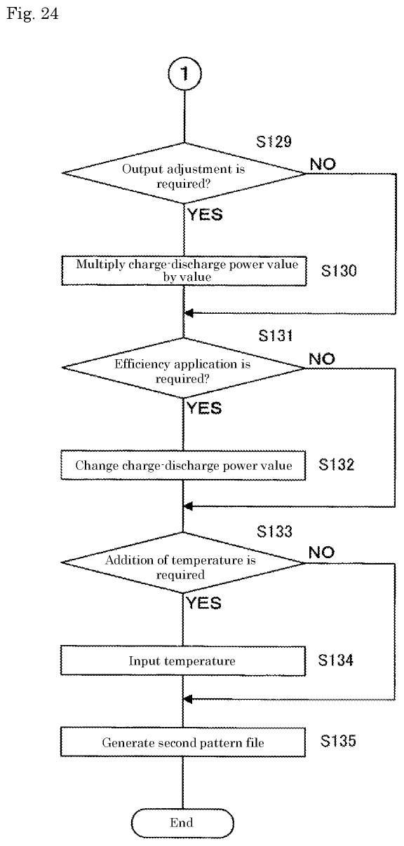

The editing processing will be described. FIGS. 23 and 24 are flowcharts illustrating the procedure of the editing processing. As described above, when the editing instruction is received, namely, when the edit button in FIG. 21 is pressed, the controller 163 executes the editing processing. In the editing processing, the controller 163 determines whether the data combination is required based on the editing content acquired in the acquisition processing, namely, the editing content selected with respect to the data combination in FIG. 21 (step S121).

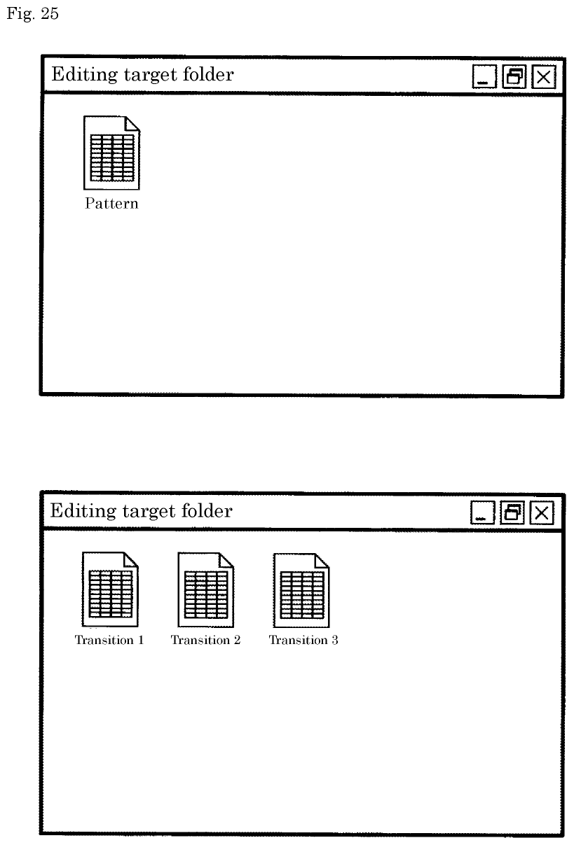

An editing target folder storing the first pattern file or the plurality of transition files is provided in the storage 162. FIG. 25 is an explanatory diagram of the editing target folder. The user inputs a file into the edit target folder by operating the operation unit 161. When the data combination is not required, the user puts one first pattern file in the edit target folder as illustrated in the upper side of FIG. 25. In the example of FIG. 25, the first pattern file having the file name “pattern” is in the edit target folder. When combining the plurality of pieces of transition data, the user puts the plurality of transition files in the editing target folder as illustrated in the lower side of FIG. 25. Three transition files are included in the example of FIG. 25. The names of the three transition files are “transition 1”, “transition 2”, and “transition 3”.

As illustrated in FIG. 23, when determining that data combination is required (YES in S121), the controller 163 combines the plurality of pieces of transition data corresponding to the plurality of transition files in the edit target folder (step S122). Thus, the first pattern data is generated. In step S122, the controller 163 sequentially combines the plurality of pieces of transitions indicated by the plurality of pieces of transition data. In the lower example of FIG. 25, the plurality of charge-discharge power values indicated by the transition data of the transition file having the file name “transition 2” are sequentially input from the line next to the last line of the transition data of the transition file having the file name “transition 1”. The plurality of charge-discharge power values indicated by the transition data of the transition file having the file name “transition 3” are sequentially input from the next line of the last line. In this manner, the controller 163 sequentially combines the plurality of transitions indicated by the plurality of pieces of transition data.

As described above, in the acquisition processing, when the controller 163 acquires the editing content indicating the requirement of the data combination, the plurality of pieces of transition data are combined in the editing processing. Accordingly, in the acquisition processing, the controller 163 acquiring the editing content indicating the requirement of the data combination corresponds to receiving the instruction to combine the plurality of pieces of transition data. The controller 163 also functions as the instruction reception unit and the combination generation unit.

When determined that the data combination is not required (NO in S121), or after executing step S122, the controller 163 determines whether the adjustment of the unit time is required based on the editing content acquired in the acquisition processing, specifically, the editing content selected with respect to the adjustment of the unit time in FIG. 21 (step S123). When determining that the adjustment of the unit time is required (YES in S123), the controller 163 determines whether one or the plurality of charge-discharge power values is thinned out from the plurality of charge-discharge power values indicated by the first pattern data based on the editing content acquired in the acquisition processing (step S124). The editing content used in step S124 is the editing content input for the editing source and the unit time after the editing in FIG. 21.

When the unit time of the editing source, namely, the unit time of the first pattern data is shorter than the unit time after the editing, namely, the unit time of the second pattern data, the controller 163 determines that one or the plurality of charge-discharge power values are thinned. When the unit time of the editing source is longer than the unit time after the editing, the controller 163 determines that one or the plurality of charge-discharge power values are not thinned. Determining that one or the plurality of charge-discharge power values are not thinned means that the interpolation of one or the plurality of charge-discharge power values is required.

When determining that one or the plurality of charge-discharge power values is thinned (YES in S124), the controller 163 thins one or the plurality of charge-discharge power values from the first pattern data based on the editing source and the unit time after the editing (step S125). In the example of FIG. 21, the unit time of the editing source is (unit time of editing)/2. For this reason, the number of charge-discharge power values indicated by the first pattern data is twice the number of charge-discharge power values indicated by the second pattern data. For example, in the first pattern data, the rows corresponding to the multiple of two, namely, the charge-discharge power values of the even-numbered rows are thinned out from the plurality of charge-discharge power values, and the charge-discharge power values of the odd-numbered rows are left. When the number of charge-discharge power values indicated by the first pattern data is three times the number of charge-discharge power values indicated by the second pattern data, for example, the charge-discharge power values other than the charge-discharge power values of the row corresponding to the multiple of 3 are thinned.

When determining that one or the plurality of charge-discharge power values are not thinned (NO in S124), the controller 163 interpolates one or the plurality of charge-discharge power values to the plurality of charge-discharge power values indicated by the first pattern data based on the editing source and the unit time after the editing (step S126). In the first pattern data, one or the plurality of charge-discharge power values are interpolated by adding one or the plurality of charge-discharge power values between two adjacent charge-discharge power values. When the unit time of the editing source is twice the unit time after the editing, the number of charge-discharge power values indicated by the first pattern data is small, namely, is (½) times the number of charge-discharge power values indicated by the second pattern data. In this case, for example, in the first pattern data, one charge-discharge power value is added between two adjacent charge-discharge power values. The added charge-discharge power value is an average value of the two adjacent charge-discharge power values, a larger charge-discharge power value of the two adjacent charge-discharge power values, or a smaller charge-discharge power value of the two adjacent charge-discharge power values.

When the number of charge-discharge power values indicated by the first pattern data is (⅓) times the number of charge-discharge power values indicated by the second pattern data, for example, the two charge-discharge power values are added between the two adjacent charge-discharge power values in the first pattern data. When step S125 or step S126 is executed, the unit time is edited from the unit time of the editing source to the unit time after the editing.

When determining that the adjustment of the unit time is not required (NO in S123), or after executing one of steps S125 and S126, the controller 163 determines whether the sign inversion is required based on the editing content acquired in the acquisition processing, specifically, the editing content selected for the inversion in FIG. 21 (step S127). When determining that the sign is required to be inverted (YES in S127), the controller 163 converts the positive value and the negative value into the negative value and the positive value, respectively, for the plurality of charge-discharge power values indicated by the first pattern data of the first pattern file (step S128). In the first pattern file, the number of the column to which the first pattern data is input is the number of the column input in the item of the reversal target column in FIG. 21.

When determining that the sign inversion is not required (NO in S127), or after executing step S128, the controller 163 determines whether the output adjustment is required based on the editing content acquired in the acquisition processing, specifically, the editing content selected for the output adjustment in FIG. 21 (step S129). As described above, for example, the output adjustment is the adjustment according to the number of energy storage apparatuses 1 included in the energy storage system 6. When determining that the output adjustment is required (YES in S129), the controller 163 multiplies each of the plurality of charge-discharge power values indicated by the first pattern data of the first pattern file by the numerical value input to the item of the output in FIG. 21 (step S130).

When determining that the output adjustment is not required (NO in S129), or after executing step S130, the controller 163 determines whether the efficiency application of the electrical component is required based on the editing content acquired in the acquisition processing, specifically, the editing content selected for the efficiency application in FIG. 21 (step S131) When determining that the efficiency application is required (YES in S131), the controller 163 changes each of the plurality of charge-discharge power values indicated by the first pattern data of the first pattern file using the efficiency corresponding to the numerical value input to the item of the efficiency in FIG. 21 (step S132).

The efficiency is a numerical value obtained by dividing the value input in the item of the efficiency by 100. This numerical value is the system efficiency Es described above. In step S132, as illustrated in equations (5) and (6), the controller 163 multiplies the charge-discharge power value indicating the charge, namely, the charge power value by the system efficiency Es among the plurality of charge-discharge power values indicated by the first pattern data. In step S132, the controller 163 divides the charge-discharge power value indicating the discharge among the plurality of charge-discharge power values indicated by the first pattern data, namely, the discharge power value by the system efficiency Es. As illustrated in FIG. 21, when each of the positive value and the negative value indicates the charge and the discharge, each positive value is multiplied by the system efficiency Es, and each negative value is divided by the system efficiency Es. Regarding steps S130 and S132, the number of the column in which the first pattern data is described in the first pattern file is the number of the column input in the item of the target column in FIG. 21.

When determining that the efficiency application is not required (NO in S131), or after executing step S132, the controller 163 determines whether the addition of the temperature is required based on the editing content acquired in the acquisition processing, specifically, the editing content selected for the version in FIG. 21 (step S133). When determining that the addition of the temperature is required (YES in S133), the controller 163 inputs the temperature in the first pattern file (step S134). The number of the column in which the temperature is input is the number of the column input in the item of the additional column.

When determining that the addition of the temperature is not required (NO in S133) or after executing step S134, the controller 163 generates the second pattern file (step S135). The second pattern file generated in step S135 is the first pattern file edited by executing at least one of steps S125, S126, S128, S130, S132, S134. After executing step S135, the controller 163 ends the editing processing. The controller 163 also functions as the editing generation unit.

In the editing of the first pattern data based on the editing content in FIG. 21, the controller 163 thins out the first pattern data input in the second column in the first pattern file, namely, the plurality of charge-discharge power values corresponding to the even-numbered rows among the plurality of charge-discharge power values, and closes an empty gap. After filling the empty gaps, the controller 163 multiplies each negative value indicating the charge by −1.94 (=(−1)·2·0.97) among the plurality of charge-discharge power values input in the second column, and overwrites the second column with the multiplied value. The controller 163 multiplies the positive value indicating the discharge by −2.06 (=(−1)·2/0·97), and overwrites the second column with the multiplied value. The controller 163 inputs 25 as the temperature to the cell in the third column adjacent to each of the plurality of charge-discharge power values described in the second column. Thus, the second pattern file is generated.

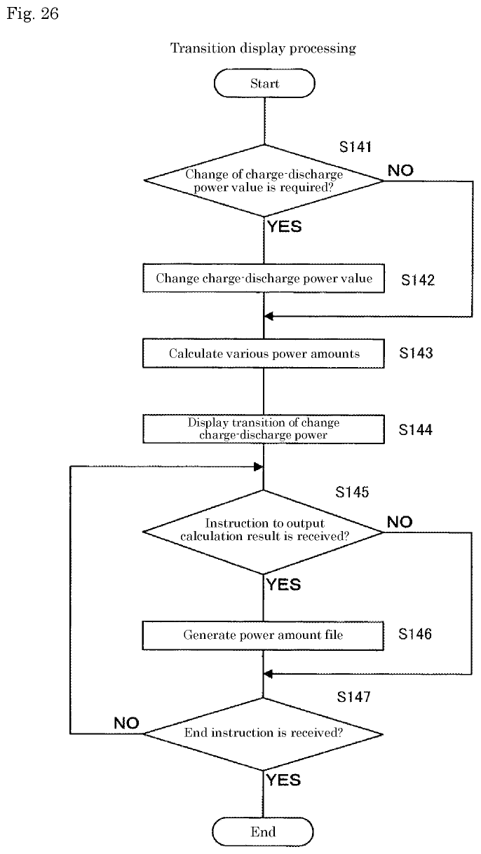

The transition display processing will be described. FIG. 26 is a flowchart illustrating the procedure of the transition display processing. As described above, when the user presses the transition display button to receive the instruction to display the graph, the controller 163 of the information processing apparatus 106 executes the transition display processing. In the transition display processing, the second pattern file selected in the item of the pattern file or the latest second pattern file generated by the controller 163 in the editing processing is used on the reception screen of the graph content in FIG. 22. In the example of FIG. 22, the second pattern file having the file name “pattern 1” is used.

In the transition display processing, the controller 163 determines whether the change of the plurality of charge-discharge power values indicated by the second pattern data of the second pattern file is required based on the graph content acquired in the acquisition processing, specifically, the editing content selected for the display unit in FIG. 22 (step S141). In step S141, when the display unit is different from kWh, the controller 163 determines that the change of the charge-discharge power value is required. When the display unit is kWh, the controller 163 determines that the change of the charge-discharge power value is not required.

When determining that the change of the charge-discharge power value is required (YES in S141), the controller 163 changes the plurality of charge-discharge power values indicated by the second pattern data (step S142). In step S142, the controller 163 changes the plurality of charge-discharge power values by dividing each of the plurality of charge-discharge power values indicated by the second pattern data by the numerical value corresponding to the selected display unit. As described above, the unit of the plurality of charge-discharge power values indicated by the second pattern data is kW. When the display unit is MWh, the numerical value used for the division is 1,000. When the display unit is GWh, the numerical value used for the division is 1,000,000. In the second pattern file, the number of the column to which the second pattern data is input is the number of the column input in the item of the display column related to the display of the transition of the charge-discharge power in FIG. 22.

When determining that the change of the charge-discharge power value is not required (NO in S141), or after executing step S142, the controller 163 calculates various amounts of power based on the graph content acquired in the acquisition processing (step S143). The display unit, the number of days, and the unit time that are illustrated in FIG. 22 are used in step S143. In FIG. 18, the time interval of one scale on the horizontal axis is the numerical value input in the item of the unit time. The predetermined period is the numerical value input in the item of the number of days, and the unit of the vertical axis is the unit selected in the item of the display unit. Under these conditions, the controller 163 calculates various amounts of power. The power amount calculated by the controller 163 will be described later.

After executing step S143, the controller 163 instructs the display 160 to display the transition of the charge-discharge power within the predetermined period indicated by the second pattern data (step S44). The display 160 displays the display screen illustrating the transition of the charge-discharge power. Thus, the person who views the display screen can easily understand the transition of the charge-discharge power indicated by the second pattern data. The display 160 functions as the transition display.

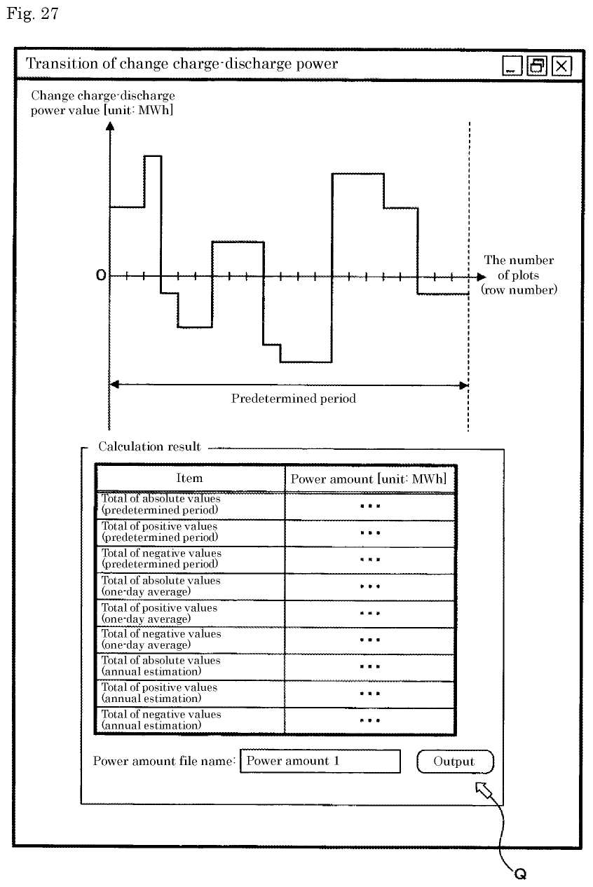

FIG. 27 is an explanatory view illustrating the display screen on which the transition of the charge-discharge power is indicated. As illustrated in FIG. 27, the display screen illustrates the transition of the charge-discharge power. The transition display method is the same as the transition display method in FIG. 19. The unit on the vertical axis corresponds to the unit selected in the item of the display unit. When the unit selected in the item of the display unit is kWh, the unit of the vertical axis is kW. When the unit selected in the item of the display unit is MWh, the unit of the vertical axis is MW. In the example of FIG. 22, in the second pattern file, the second pattern data input in the second column is displayed on the display screen. The time interval of one scale on the horizontal axis is one second, the predetermined period is five days, and the unit on the vertical axis is MWh.

In the case where various amounts of power are calculated in step S143, when the numerical value input in the item of the unit time is X, one scale is X seconds, namely, (X/3600) hours. A first power amount calculated in step S143 is the total of the amounts of power of the absolute values of the charge-discharge power values indicated by the second pattern data within the predetermined period. This is calculated by integrating the absolute value of the charge-discharge power value within the predetermined period. A second power amount is the total of the positive amounts of power indicated by the second pattern data within the predetermined period. This is calculated by integrating the positive value within the predetermined period. In the example of FIG. 21, the positive value is the charge power value. A third power amount is the total of the power amounts of the absolute values of the negative values indicated by the second pattern data within the predetermined period. This is calculated by integrating the negative value within the predetermined period and changing the integrated value to the positive value.

A fourth amount of power is the average value per day related to the total of the amounts of power of the absolute values of the charge-discharge power values indicated by the second pattern data within the predetermined period. A fifth power amount is the average value per day related to the total of the amounts of power of the positive values indicated by the second pattern data within the predetermined period. A sixth power amount is the average value per day related to the total of the amounts of power of the absolute values of the negative values indicated by the second pattern data within the predetermined period. In the example of FIG. 22, because the predetermined period is five days, the fourth, fifth, and sixth power amounts are calculated by dividing the first, second, and third power amounts by five, respectively.

A seventh power amount is an estimated value of the power amount consumed per year with respect to the absolute value of the charge-discharge power value. An eighth power amount is an estimated value of the power amount consumed per year for the positive value. A ninth power amount is an estimated value of the power amount consumed per year for the absolute value of the negative value. The seventh, eighth, and ninth power amounts are calculated by multiplying the fourth, fifth, and sixth power amounts by 365, respectively.

In the transition display screen of FIG. 27, the user can press the output button using the operation unit 161. When the user presses the output button, the controller 163 receives an instruction to output the calculation result of the amount of power. In the item of the power amount file name, the user can input the name of the power amount file indicating the calculation result of the power amount by operating the operation unit 161. In the example of FIG. 27, a power amount 1 is input as the power amount file name.

As illustrated in FIG. 26, after executing step S144, the controller 163 determines whether the instruction to output the calculation result of the power amount is received (step S145). When determining that the instruction to output the calculation result is received (YES IN S145), the controller 163 generates the power amount file indicating the calculation result of the power amount displayed on the display screen (step S146). The name of the power amount file is a name input in the power amount file name indicated in the display screen of FIG. 27.

When determining that the instruction to output the calculation result is not received (NO in S145), or after executing step S146, the controller 163 determines whether an instruction to end the display is received (step S147). For example, in the display screen of FIG. 27, the end instruction is received when the user presses the button indicated by the X mark. When determining that the end instruction is not received (NO in S147), the controller 163 executes step S145 and waits until the end instruction is received. When determining that the end instruction is received (YES IN S147), the controller 163 ends the transition display processing.

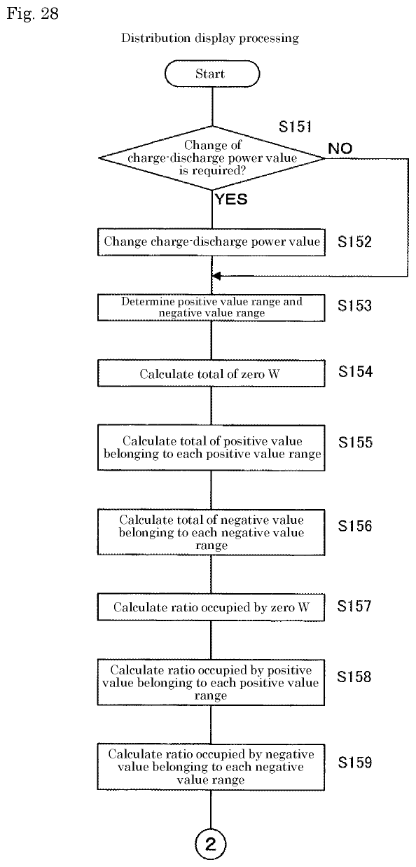

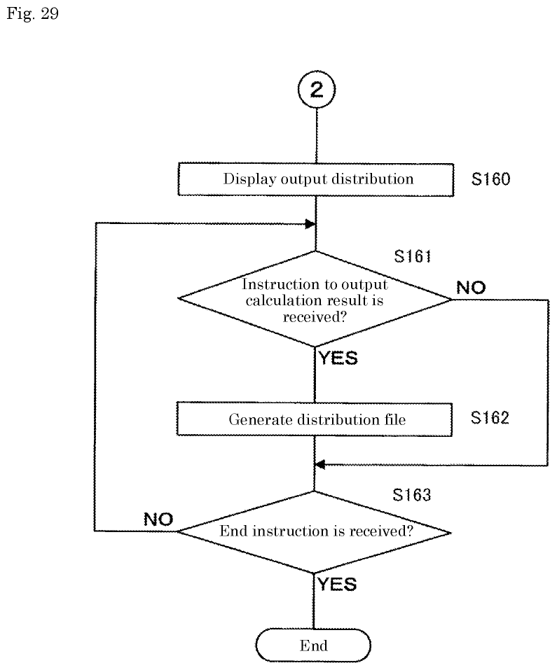

The distribution display processing will be described. FIGS. 28 and 29 are flowcharts illustrating the procedure of the distribution display processing. As described above, when the user presses the distribution display button to receive the instruction to display the graph, the controller 163 of the information processing apparatus 106 executes the distribution display processing. In the distribution display processing, the second pattern file selected in the item of the pattern file or the latest second pattern file generated by the controller 163 in the editing processing is used on the reception screen of the graph content in FIG. 22. In the example of FIG. 22, the second pattern file having the file name “pattern 1” is used.

In the distribution display processing, the controller 163 determines whether the change of the plurality of charge-discharge power values indicated by the second pattern data of the second pattern file is required based on the graph content acquired in the acquisition processing, specifically, the graph content selected for the display unit in FIG. 22 (step S151). In step S151, when the display unit is different from kW, the controller 163 determines that the change of the charge-discharge power value is required. When the display unit is kW, the controller 163 determines that the change of the charge-discharge power value is not required.

When determining that the change of the charge-discharge power value is required (YES in S151), the controller 163 changes the plurality of charge-discharge power values indicated by the second pattern data (step S152). In step S152, the controller 163 changes the plurality of charge-discharge power values by dividing each of the plurality of charge-discharge power values indicated by the second pattern data by the numerical value corresponding to the selected display unit. As described above, the unit of the plurality of charge-discharge power values indicated by the second pattern data is kW. When the display unit is MW, the numerical value used for the division is 1000. When the display unit is GW, the numerical value used for the division is 1,000,000. In the second pattern file, the number of the column to which the second pattern data is input is the number of the column input in the item of the display column related to the display of the transition of the charge-discharge power in FIG. 22.

When determining that the change of the charge-discharge power value is not required (NO in S151), or after executing step S152, the controller 163 determines the plurality of positive value ranges and the plurality of negative value ranges based on the graph content acquired in the acquisition processing (step S153). In step S153, the display unit, the maximum value, and the number of divisions in FIG. 22 are used.

When the item of the maximum value in FIG. 22 is blank, the maximum value of the absolute value of the charge-discharge power value indicated by the second pattern data is used. The range from zero W to the maximum value is divided into the plurality of positive value ranges. The number of positive value ranges is matched with the number of divisions. The size of each positive value range is the numerical value obtained by dividing the maximum value by the number of divisions. In the example of FIG. 22, because 1500 [MW] is input as the maximum value and five is input as the division number, the plurality of positive value ranges are determined to be the range of zero to 300 [MW], the range of 300 to 600 [MW], and the like. As described above, the plurality of negative value ranges are the same as the plurality of positive value ranges.

After executing step S153, the controller 163 calculates the total of zero W included in the plurality of charge-discharge power values indicated by the second pattern data (step S154). Subsequently, the controller 163 calculates the total of positive values belonging to each positive value range among the plurality of charge-discharge power values indicated by the second pattern data (step S155). Each positive value range is the range determined in step S153. In step S155, for example, the controller 163 calculates the total of positive values belonging to the positive value range of zero to 300 [MW], the total of positive values belonging to the positive value range of 300 to 600 [MW], and the like among the plurality of charge-discharge power values indicated by the second pattern data.

Subsequently, similarly to step S155, the controller 163 calculates the total of negative values belonging to each negative value range among the plurality of charge-discharge power values indicated by the second pattern data (step S156). Each negative value range is also the range determined in step S153. After executing step S156, the controller 163 calculates the ratio occupied by zero W among the plurality of charge-discharge power values indicated by the second pattern data (step S157). Subsequently, the controller 163 calculates the ratio of the positive value belonging to each positive value range among the plurality of charge-discharge power values indicated by the second pattern data (step S158). Each positive value range is the range determined in step S153. Subsequently, the controller 163 calculates the ratio of the negative value belonging to each negative value range among the plurality of charge-discharge power values indicated by the second pattern data (step S159). Each positive value range and each negative value range are the ranges determined in step S153. The controller 163 functions as the charge ratio calculator and the discharge ratio calculator.

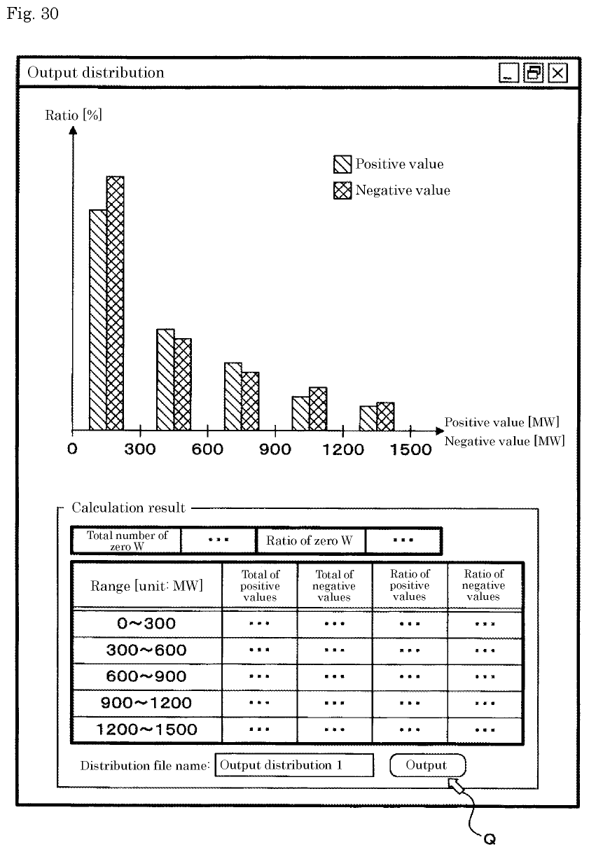

Subsequently, the controller 163 instructs the display 160 to display the output distribution of the second pattern data (step S160). The display 160 displays the display screen illustrating the output distribution. FIG. 30 is an explanatory view illustrating the display screen on which the output distribution is displayed. As illustrated in FIG. 30, the output distribution of the second pattern data is displayed on the display screen. A method for displaying the output distribution in FIG. 30 is similar to the method for displaying the output distribution in FIG. 19. The unit on the horizontal axis corresponds to the unit selected in the item of the display unit. For example, when the unit selected in the item of the display unit is kW, the unit of the horizontal axis is kW. In the output distribution, the calculation results calculated in steps S158, S159 are indicated by bar graphs. For example, the positive value and the negative value indicate the charge and the discharge, respectively. By displaying the output distribution, a person who looks at the output distribution can easily understand the tendency related to the charge and the discharge.

The display screen of the output distribution also illustrates the calculation results calculated in steps S154 to S157. On the display screen of the output distribution, the user can press the output button using the operation unit 161. When the user presses the output button, the controller 163 receives the instruction to output the calculation results of the total and the ratio. In the item of the distribution file name, the user can input the name of the distribution file indicating the calculation result of the total and the ratio by operating the operation unit 161. In the example of FIG. 30, the output distribution is input as the distribution file name.

As illustrated in FIG. 29, after executing step S160, the controller 163 determines whether the instruction to output the calculation results of the total and the ratio is received (step S161). When determining that the instruction to output the calculation result is received (YES in S161), the controller 163 generates the distribution file indicating the calculation results of the total and the ratio displayed on the display screen (step S162). The name of the distribution file is a name input in the distribution file name indicated in the display screen of FIG. 30.

When determining that the instruction to output the calculation result is not received (NO in S161), or after executing step S162, the controller 163 determines whether the instruction to end the display is received (step S163). For example, in the display screen of FIG. 30, when the user presses the button indicated by the X mark, the end instruction is received. When determining that the end instruction is not received (NO in S163), the controller 163 executes step S161 and waits until the end instruction is received. When determining that the end instruction is received (YES in S163), the controller 163 ends the distribution display processing.

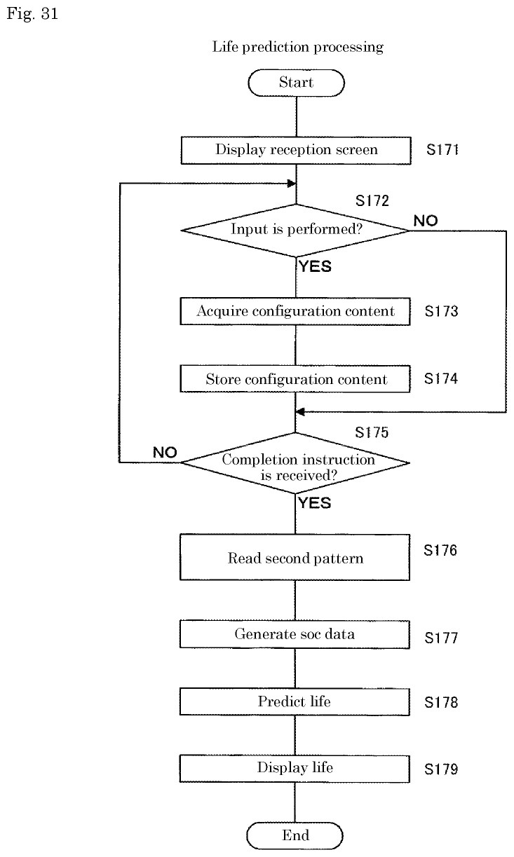

The life prediction processing will be described. FIG. 31 is a flowchart illustrating the procedure of the life prediction processing. The user of the information processing apparatus 106 instructs the execution of the life prediction processing by operating the operation unit 161. In the life prediction processing, the second pattern data indicated by the second pattern file designated by the user is used among the second pattern files stored in the storage 162. In the life prediction processing, the controller 163 instructs the display 160 to display the reception screen receiving the configuration content of the energy storage apparatus 1 in FIG. 4 (step S171).

As illustrated in FIG. 31, after executing step S171, the controller 163 determines whether the user performs the input related to the editing content (step S172). When determining that the input is performed (YES in S172), the controller 163 acquires the configuration content of the energy storage apparatus 1 input by the user (step S173), and stores the acquired configuration content of the energy storage apparatus 1 in the storage 162 (step S174). When determining that the input is not performed (NO in S172) or after executing step S174, the controller 163 determines whether the instruction to complete the reception of the configuration content is received (step S175). When determining that the completion instruction is not received (NO in S175), the controller 163 executes step S172 and repeatedly acquires the configuration content until the completion instruction is received.

When determining that the completion instruction is received (YES in S175), the controller 163 reads the second pattern file designated by the user from the storage 162 (step S176). Subsequently, the controller 163 generates the SOC data indicating the transition of the SOC of the energy storage apparatus 1 based on the second pattern data input in the second pattern file read in step S176 (step S177). The controller 163 predicts the transition of the charge-discharge power based on the second pattern data indicating the transition of the charge-discharge power of energy storage apparatus 1 within the predetermined period. For example, when the predetermined period is one day, the controller 163 predicts the transition of daily charge-discharge power based on the second pattern data. When the transition of the charge-discharge power indicated by the second pattern data is the transition of the charge-discharge power of the plurality of energy storage apparatuses 1, the controller 163 predicts the transition of the charge-discharge power per energy storage apparatus 1 in step S177. For example, each of the plurality of pieces of charge-discharge power indicated by the second pattern data is divided by the number of energy storage apparatuses

Based on the predicted transition of the charge-discharge power, for example, the controller 163 calculates the amounts of the charge power and the discharge power in the period from the start of the use of the energy storage apparatus 1 to the calculation time point. The controller 163 calculates the SOC at the calculation time point by subtracting the power amount of the discharge power from the power amount of the charge power. The controller 163 calculates the SOC at each time point by changing the calculation time point to each of the plurality of time points engraved at a predetermined time, for example, at an interval of one second, and generates the SOC data indicating the transition of the SOC.

Subsequently, the controller 163 predicts the life of the energy storage apparatus 1 as the prediction of the degradation of the energy storage apparatus 1 based on the SOC data generated in step S177 and the configuration content of the energy storage apparatus 1 stored in the storage 162 in step S174 (Step S178). As described above, the life is a period from the start of the use until the capacity of the energy storage apparatus 1 decreases to a predetermined value, for example, a period until the state of health (SOH) decreases to 70%. The prediction of the life is an example of the prediction of the degradation. SOH is a ratio of the capacity of the energy storage apparatus 1 when the capacity of the energy storage apparatus 1 at the start of the use is set to 100%. According to the version of the simulation software, in step S178, the controller 163 predicts the life of the energy storage apparatus 1 based on not only the SOC data and the configuration content but also the temperature in the energy storage apparatus 1 input to the second pattern data. The controller 163 also functions as the prediction unit.

The prediction of the life of the energy storage apparatus 1 based on the SOC data can be implemented using a known technique, for example, a technique described in JP-A-2018-169393. Subsequently, the controller 163 instructs the display 160 to display the life predicted in step S178 (step S179), and ends the life prediction processing.

The user of the information processing apparatus 106 inputs various configuration contents of the energy storage apparatus 1, and causes the controller 163 to repeatedly execute the life prediction processing. Thus, the user searches the optimum configuration content of the energy storage apparatus 1 that satisfies the requirement of the customer who is scheduled to order the energy storage apparatus 1. The user of the information processing apparatus 106, for example, the manufacturer of the energy storage apparatus 1 proposes the energy storage apparatus 1 having the optimum configuration content to the customer.

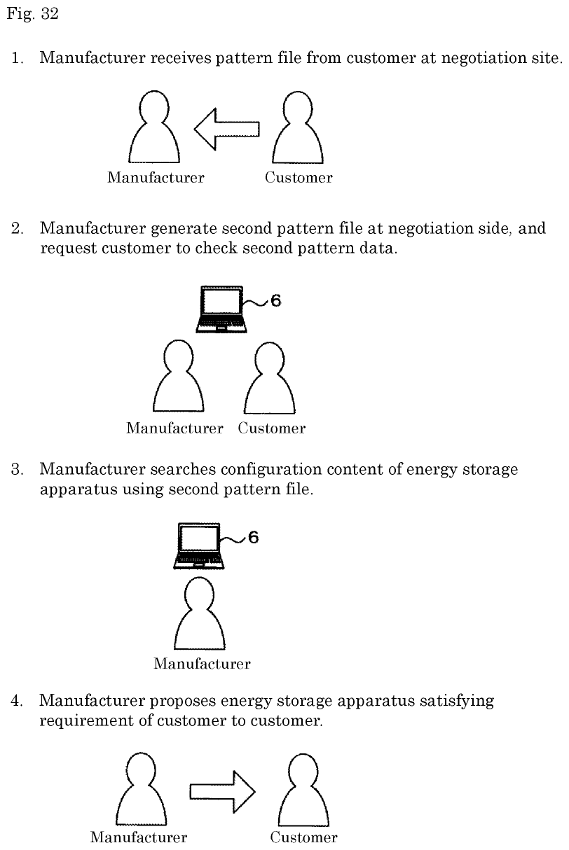

A use example of the information processing apparatus 106 will be described. FIG. 32 is an explanatory diagram illustrating the usage example of the information processing apparatus 106. The manufacturer of the energy storage apparatus 1 receives the pattern file from the customer at the negotiation place. At this point, sometimes the following problems are generated. As a first problem, the customer may pass a plurality of divided transition files as the pattern file to the manufacturer. As a second problem, there is a possibility that the plurality of charge-discharge power values indicated by the pattern data input to the pattern file are not the charge-discharge power value of the energy storage apparatus 1 but the charge-discharge power value of the energy storage system 6.

As a third problem, although the energy storage system 6 including the plurality of power conditioners 61 is considered, there is a possibility that the plurality of charge-discharge power values indicated by the pattern data input to the pattern file are the charge-discharge power values related to the input and output of one power conditioner 61. As a fourth problem, there is a possibility that the temperature in the energy storage apparatus 1 is not described in the pattern file in spite of the fact that the temperature in the energy storage apparatus 1 is required in the case of predicting the life.

As a fifth problem, there is a possibility that the definitions of the positive value and the negative value of the pattern data input to the pattern file are different from the definitions performed by the manufacturer. For example, in spite of the fact that the manufacturer company defines the positive value and the negative value as the charge and the discharge, respectively, there is a possibility that the positive value and the negative value of the pattern data are defined as the discharge and the charge, respectively. As a sixth problem, there is a possibility that the unit time of the pattern data input to the pattern file is not appropriate. For example, although the pattern data having the unit time of one second is required, there is a possibility that the unit time of the pattern data may be 15 seconds.

Conventionally, when the first problem is generated, the manufacturer generates the first pattern file or the second pattern file using spreadsheet software. When the second to sixth problems are generated, the pattern file received from the customer is the first pattern file in which the editing is required. The manufacturer produces the second pattern file by editing the first pattern file using the spreadsheet software. When the generation or the editing is performed, the number of operations performed by the manufacturer is large, and a lot of time is spent. For this reason, the manufacturer returns to the company from the negotiation site, and performs the above-described operation to generate the second pattern file.

Based on the generated second pattern file, the manufacturer determines the configuration content of the energy storage apparatus satisfying the life requested by the customer. The manufacturer goes to the negotiation again, and presents the second pattern data and the determined configuration contents to the customer. When the presented second pattern data is different from the pattern data assumed by the customer, the manufacturer needs to return to own company and generate or edit the second pattern data again, which takes a lot of time.

When the manufacturer brings the information processing apparatus 106 to the negotiation site, the manufacturer can cause the information processing apparatus 106 to immediately generate the second pattern file at the negotiation site only by selecting and inputting the editing content in FIG. 21. In the first problem, the manufacturer combines the plurality of transition files by the information processing apparatus 106 to generate the first pattern file or the second pattern file. In the second problem, the manufacturer inputs the system efficiency in the information processing apparatus 106. Based on the system efficiency input by the manufacturer, the information processing apparatus 106 changes the charge-discharge power value indicated by the first pattern data of the first pattern file provided by the customer to the charge-discharge power value of energy storage apparatus 1. In the third problem, the manufacturer inputs the multiple corresponding to the number of power conditioners 61 in the information processing apparatus 106. The information processing apparatus 106 multiplies the charge-discharge power value indicated by the first pattern data of the first pattern file provided by the customer by the multiple input by the manufacturer.

In the fourth problem, the manufacturer inputs the temperature in the energy storage apparatus 1. The information processing apparatus 106 inputs the temperature input by the manufacturer in the first pattern file provided by the customer. In the fifth problem, the manufacturer instructs the information processing apparatus 106 to invert the positive value and the negative value. The information processing apparatus 106 converts the positive value and the negative value indicated by the first pattern data of the first pattern file provided by the customer into the negative value and the positive value, respectively. In the sixth problem, the manufacturer checks the unit time of the pattern data (first pattern data) provided from the customer, and determines the unit time of the second pattern data generated using the first pattern data. For example, the user inputs the unit time of the checked first pattern data and the unit time of the determined second pattern data. The information processing apparatus 106 acquires two unit times input by the manufacturer, and generates the second pattern data based on the acquired two unit times.

The manufacturer can immediately generate the second pattern file, and display the transition and output distribution of the charge-discharge power in FIGS. 27 and 30 on the information processing apparatus 106 to request the customer to check the second pattern data. When the customer does not properly understand the pattern data of the pattern file that the customer passes to the manufacturer, the customer understands the pattern data of the pattern file that the customer passes to the manufacturer at this point. When the generated second pattern data is different from the pattern data assumed by the customer, the manufacturer may change the editing content and edit the first pattern data again at the negotiation site.

When the manufacturer can agree with the customer on the second pattern data, the manufacturer inputs the configuration contents of the energy storage apparatus 1 in the information processing apparatus 106, and causes the controller 163 of the information processing apparatus 106 to execute the life prediction processing. The controller 163 predicts the life of the energy storage apparatus 1 having the different configuration content using the generated second pattern file. Thus, the manufacturer searches the configuration content of the energy storage apparatus 1 that satisfies the requirement of the customer. The manufacturer presents the customer with the configuration content of the energy storage apparatus 1 that satisfies the requirement of the customer. Because the information processing apparatus 106 also performs the life prediction processing, the manufacturer can present the configuration content of the energy storage apparatus 1 that satisfies the requirement of the customer to the customer at the negotiation site.

The information processing apparatus 106 can execute the acquisition processing, the editing processing, the transition display processing, and the distribution processing with respect to the data indicating the transition of the charge-discharge power. Accordingly, the information processing apparatus 106 may edit not only the second pattern file (second pattern data) used for the life prediction of the newly-manufactured energy storage apparatus 1 but also history data or operation data indicating the transition of the charge-discharge power that the already manufactured energy storage apparatus 1 performed in the past. For example, the edited data is used for the estimation of the current SOH. Examples of the energy storage apparatus 1 include an energy storage apparatus mounted on a vehicle and an energy storage apparatus disposed in a stationary energy storage system. The life prediction processing of the energy storage apparatus 1 may be performed by an apparatus different from the information processing apparatus 106.

It should be understood that the embodiment disclosed herein is illustrative in all points and not restrictive. The scope of the present invention is illustrated by not the above meanings, but the scope of the claims, and is intended to include all changes within the scope of the claims and meaning equivalent to the scope of the claims.

1. A generation apparatus comprising:
a screen display that displays a reception screen in order to receive at least one of selection or input related to charge-discharge of an energy storage system including an energy storage apparatus;
a selection reception unit that accepts selection from a plurality of types of operations related to the charge-discharge on the reception screen; and
a generation unit that generates pattern data that is used for prediction of degradation of the energy storage apparatus and indicates transition of a charge-discharge amount of the energy storage apparatus within a predetermined period based on the operation selected through the selection reception unit.

2. The generation apparatus according to claim 1, wherein the plurality of types of operations include at least two of: operation in which only charge is performed, operation in which only discharge is performed, and operation in which the charge and the discharge are continuously performed once each.

3. The generation apparatus according to claim 1, further comprising a power reception unit that receives input of both or one of a charge amount and a discharge amount on the reception screen for the operation selected through the selection reception unit.

4. The generation apparatus according to claim 1, further comprising a first efficiency reception unit that receives input of transmission efficiency of a power line of the energy storage system on the reception screen.

5. The generation apparatus according to claim 1, further comprising a second efficiency reception unit that receives input of conversion efficiency of a converter of the energy storage system on the reception screen.

6. The generation apparatus according to claim 5, further comprising a third efficiency reception unit that receives input of conversion efficiency of a transformer of the energy storage system on the reception screen.

7. A prediction system comprising:
the generation apparatus according to claim 1;
a configuration reception unit that receives a configuration of the energy storage apparatus; and
a prediction unit that predicts degradation of the energy storage apparatus based on pattern data generated by the generation apparatus and a configuration received by the configuration reception unit.

8. A generation method comprising:
displaying a reception screen in order to receive at least one of selection or input related to charge-discharge of an energy storage system including an energy storage apparatus;
acquiring operation data indicating operation selected from a plurality of types of operations related to the charge-discharge on the reception screen; and
generating pattern data that is used for prediction of degradation of the energy storage apparatus and indicates transition of a charge-discharge amount of the energy storage apparatus within a predetermined period based on acquired operation data.

9. A generation apparatus comprising:
an information acquisition unit that acquires editing information used for editing first pattern data indicating transition of charge-discharge power related to an energy storage apparatus within a predetermined period; and
an editing generation unit that edits the first pattern data based on the editing information acquired by the information acquisition unit to generate second pattern data that is used for prediction of degradation of the energy storage apparatus and indicates the transition of the charge-discharge power of the energy storage apparatus within the predetermined period.

10. The generation apparatus according to claim 9, further comprising a display that displays a reception screen in order to receive the editing information,
wherein
the information acquisition unit acquires the editing information through the reception screen, and
the reception screen further receives graph information used to generate a graph.

11. The generation apparatus according to claim 9, further comprising:
an instruction reception unit that receives a combination instruction of a plurality of pieces of transition data indicating the transition of the charge-discharge power related to the energy storage apparatus; and
a combination generation unit that generates the first pattern data by sequentially combining a plurality of transitions indicated by the plurality of pieces of transition data when the instruction reception unit receives the combination instruction.

12. The generation apparatus according to claim 9, wherein:
the first pattern data and the second pattern data are data in which a plurality of charge-discharge power values are listed for each unit time,
the information acquisition unit acquires a first unit time and a second unit time corresponding to the first pattern data and the second pattern data, and
the editing generation unit generates the second pattern data in which the plurality of charge-discharge power values are listed for each second unit time acquired by the information acquisition unit based on the first unit time and the second unit time acquired by the information acquisition unit.

13. The generation apparatus according to claim 9, wherein:
the information acquisition unit acquires efficiency related to power of an electric component when the charge-discharge power related to the energy storage apparatus is the charge-discharge power of the energy storage system in which charge-discharge of the energy storage apparatus is performed through the electric component, and
the editing generation unit edits the first pattern data to change a plurality of charge-discharge power values indicated by the first pattern data based on the efficiency acquired by the information acquisition unit.

14. The generation apparatus according to claim 9, further comprising:
a content acquisition unit that acquires a configuration content of the energy storage apparatus; and
a prediction unit that predicts degradation of the energy storage apparatus based on the second pattern data generated by the editing generation unit and the configuration content acquired by the content acquisition unit.

15. The generation apparatus according to claim 2, further comprising a power reception unit that receives input of both or one of a charge amount and a discharge amount on the reception screen for the operation selected through the selection reception unit.

16. The generation apparatus according to claim 10, further comprising:
an instruction reception unit that receives a combination instruction of a plurality of pieces of transition data indicating the transition of the charge-discharge power related to the energy storage apparatus; and
a combination generation unit that generates the first pattern data by sequentially combining a plurality of transitions indicated by the plurality of pieces of transition data when the instruction reception unit receives the combination instruction.
